(19) United States
(12) Patent Application Publication
(10) Pub. No.: US 2016/0087028 A1
(43) Pub. Date: Mar. 24, 2016

(54) SEMICONDUCTOR DEVICE AND METHOD FOR MANUFACTURING SAME

(71) Applicants: Toshiyuki HIROTA, Tokyo (JP); Takakazu MATSUI, Tokyo (JP); PS4 LUXCO S.A.R.L., Luxembourg (LU)

(72) Inventors: Toshiyuki Hirota, Tokyo (JP); Takakazu Matsui, Tokyo (JP)

(21) Appl. No.: 14/892,928

(22) PCT Filed: May 14, 2014
(86) PCT No.: PCT/JP2014/062823

§ 371 Date: Nov. 20, 2015

(30) Foreign Application Priority Data
May 21, 2013 (JP) 2013-106832

(51) Int. Cl. H01L 49/02; H01L 21/02

(52) U.S. Cl. CPC H01L 28/60; H01L 21/02186; H01L 21/02189; H01L 21/0228; H01L 21/02244; H01L 21/02164; H01L 21/02211

(57) ABSTRACT

One semiconductor device includes a capacitor having a lower electrode which is arranged on a semiconductor substrate, a second protective film, a dielectric film which has a defect that extends in the film thickness direction from an upper surface that faces the second protective film, a third protective film which has at least a defect filling film that is formed of an insulating body filling the defect, a first protective film which covers the dielectric film and the third protective film, and an upper electrode which covers the first protective film.

### TECHNICAL FIELD

The present invention relates to a semiconductor device and to a method for manufacturing same, and more specifically the present invention relates to a semiconductor device having a capacitor comprising a dielectric film having a high dielectric constant.

### BACKGROUND

There is a growing demand for semiconductor devices comprising memory elements which are miniaturized and have a high bit number. A dielectric film having a high dielectric constant is used in a capacitor having this kind of memory element.

The capacitor illustrated in FIG. 2 of Patent Document 1 (JP 2006-135339 A), for example, has a layered structure in which the following are stacked in succession from a lower layer, namely: a storage electrode (15); an AZ structure dielectric film (16) comprising a first dielectric film (16A) that comprises an ALD (atomic layer deposition)-ZrO (zirconium oxide) film, and a second dielectric film (16B) that comprises an ALD-AlO (aluminum oxide) film; and a plate electrode (17) comprising a CVD (chemical vapor deposition)-TiN (titanium nitride) film. It should be noted that the AZ structure denotes a structure comprising an A10 upper layer as A and a ZrO lower layer as Z, from the upper layer toward the lower layer. For example, a TZT structure which will be described later means a combination of TiO as T and ZrO as Z, where ZrO is combined between upper and lower layers of TiO. Furthermore, the numbers in parentheses indicate the reference symbols in the figures of the corresponding prior art and are distinct from the reference symbols in the figures of the present invention; the same also applies to the prior art below.

The abovementioned document indicates that by virtue of the abovementioned structure, a capacitor having a small leakage current can be formed, even when the inevitable heat treatment is carried out after the capacitor has been formed, and a ZA structure, a ZAZ structure or other structures in which said structures are stacked multiple times are also described, in addition to the AZ structure. It is also indicated that the film thickness of AlO is in the range of 0.5 nm-3 nm and the film thickness of ZrO is in the range of 0.5 nm to 10 nm. It is further indicated that the storage electrode constituting a lower electrode and the plate electrode constituting an upper electrode are formed by any materials selected from the group consisting of metals such as W, Ru, Ir and Pt; metallic compounds such as TiN, TaN, WN, RuO and IrO; and impurity-doped polycrystalline silicon. It is also indicated that the dielectric constant of a ZrO film obtained using the abovementioned technology is 20-25 and the dielectric constant of an AlO film is 9.

Furthermore, the capacitor illustrated in FIG. 5I of Patent Document 2 (JP 2012-104719 A) has a structure in which the following are stacked in succession from a lower layer, namely: a lower electrode (23) comprising an ALD-TiN film connected to a contact (12); a dielectric film (30) having a ZAT structure consisting of a first dielectric film (32) comprising ALD-ZrO, a second dielectric film (34) comprising an ALD-AlO film, and a third dielectric film (36) comprising an ALD-TiO film; and an upper electrode (43) comprising an ALD-TiN film. However, said document merely describes the structure and film formation method, and there is no mention of conditions such as film thickness for obtaining a high-performance capacitor.

In addition, Patent Document 3 (JP 2012-80095 A), Patent Document 4 (JP 2012-80094 A) and Patent Document 5 (JP 2012-69871 A) filed by the present inventors propose forming a protective film of titanium oxide between an electrode and a dielectric film comprising zirconium oxide.

As shown in FIG. 13 of Patent Document 3, a capacitor has a TZT structure comprising, from a lower layer: a lower electrode (102) comprising a CVD-TiN (titanium nitride) film; a second protective film (114) comprising an ALD-TiO (titanium oxide) film; a dielectric film (115) comprising an ALD-ZrO film; a first protective film (116) comprising an ALD-TiO film; and an upper electrode (117) comprising a CVD-TiN film. It is indicated that by providing the second protective film (114) comprising a titanium oxide film between the lower electrode (102) and the dielectric film (115), adhesion between the lower electrode (102) and the dielectric film (115) is improved and peeling is unlikely to occur, the crystallinity of the dielectric film (115) comprising a zirconium oxide film is improved, and a higher dielectric constant can be achieved. It is further indicated that by providing the first protective film (116) comprising a titanium oxide film between the dielectric film (115) and the upper electrode (117), the dielectric film (115) is protected from damage (cracking and pin hole formation, and etching and oxygen deficiency) imparted when the upper electrode (117) is formed, the leakage current is reduced, and it is possible to obtain a capacitor having favorable characteristics.

As illustrated in FIG. 10 of Patent Document 4, a capacitor has a TZAZT structure comprising: a lower electrode (102) comprising a CVD-TiN film; a second protective film (108) comprising an ALD-TiO film; a first dielectric film (105) comprising an ALD-ZrO film; a second dielectric film (106) comprising an ALD-AlO film; a third dielectric film (107) comprising an ALD-ZrO film; a first protective film (110) comprising an ALD-TiO film; and an upper electrode (111) comprising a CVD-TiN film. In the abovementioned structure, the first dielectric film (105) and the third dielectric film (107) comprising a ZrO film may have the same thickness or different thicknesses such that the first electrode film (105) has a thickness of 5 nm, for example, and the third dielectric film (107) has a thickness of 1 nm, for example. It is indicated that by adopting a TZAZT structure in which an AlO film is interposed as the second dielectric film (106), it is possible to obtain a capacitor which has an even smaller leakage current than a capacitor having a TZT structure, in addition to the advantages described in Patent Document 3.

As illustrated in FIG. 2 of Patent Document 5, a capacitor has a structure comprising, in succession from a lower layer: a lower electrode (201) comprising a CVD-TiN film; a second protective film (202) having an ALD-TiO film; a first dielectric film (203) comprising an ALD-ZrO film; an Al-doped layer (204) including AlO formed by means of adsorption site blocking-ALD (ASB-ALD); a second dielectric film (205) comprising an ALD-ZrO film; a first protective film (206) comprising an ALD-TiO film; and an upper electrode (207) comprising a CVD-TiN film. The ASB-ALD technique developed by the present inventors makes it possible to reduce the amount of Al per ALD cycle for Al doping, and the heat resistance can be improved while the continuity of crystals in the ZrO films positioned above and below the Al-doped layer can be maintained at an advantageous level. As a result, it is possible to realize a smaller equivalent oxide thickness (EOT: capacitance value per unit surface area expressed as the equivalent thickness of a silicon dioxide (SiO₂, dielectric constant: 3.9) film) in comparison with a conventional capacitor. “Cyclopentadienyl tris(dimethylamino)zirconium” and “methylcyclopentadienyl tris(dimethylamino)zirconium” are mentioned as precursors of zirconium (Zr) used in the ASB-ALD, and “methylcyclopentadienyl tris(dimethylamino)titanium” is mentioned as a precursor of titanium (Ti).

Furthermore, Patent Document 6 (JP 2012-248813 A) filed by the present inventors indicates that a TiO film having a rutile crystal structure with a high dielectric constant is obtained under specific conditions, namely conditions such that an amorphous titanium oxide (TiO) film is formed on an amorphous zirconium film by means of ALD using methylcyclopentadienyl tris(dimethylamino)titanium as a titanium starting material, and heat treatment is carried out at a temperature of 300° C. or greater.

### PATENT DOCUMENTS

Patent Document 1: JP 2006-135339 A
Patent Document 2: JP 2012-104719 A
Patent Document 3: JP 2012-080095 A
Patent Document 4: JP 2012-080094 A
Patent Document 5: JP 2012-069871 A
Patent Document 6: JP 2012-248813 A

### SUMMARY OF THE INVENTION

### Problems to be Solved by the Invention

If the minimum processing size dictated by the resolution limit of lithography is F, then a capacitor having an EOT of 0.75 nm or less is required as a capacitor for a DRAM in which F is at the 25 nm level onward. Furthermore, the leakage current (leak current) at 90° C. ensuring reliability must be 10 (fA/cell) or less under an applied voltage of ±1 V. In addition, in terms of an actual device, each memory cell must have a memory retention time (holding time) equal to or greater than a given value which is determined by the refresh interval. In other words, there is a need for a very reliable capacitor which has a small EOT and a small leakage current.

Types of leakage current in an insulating film which may be considered include Schottky current, Pool-Frenkel current and tunneling current, but even assuming that a Schottky barrier has sufficient height and an ideal dielectric film has no defects, tunneling currents such as Fowler-Nordheim tunneling current and direct tunneling current are important.

A tunneling current depends greatly on film thickness and although there is a sharp increase in tunneling current when the film thickness drops below a certain level, experiments have shown that the thickness of the dielectric film as a whole must be a minimum of 5 nm in order to satisfy the abovementioned leakage current specification.

In the method for forming a capacitor described in Patent Document 1, the dielectric constant of zirconium oxide is only 20-25, as also indicated in Patent Document 1. This is believed to be due to the fact that amorphous material having a low dielectric constant and cubic microcrystals having low density and also having a low dielectric constant are predominant in the dielectric film. When amorphous or microcrystalline zirconium oxide is formed into a dielectric film, virtually no problems arise in the dielectric film, such as cracking or pin holes accompanying thermal load when the upper electrode is formed, and therefore it is possible to achieve relatively good leakage current characteristics. It is difficult, however, to obtain a small EOT because of this low dielectric constant.

For example, a dielectric film in which a zirconium oxide film (dielectric constant: 25) and an aluminum oxide film (dielectric constant: 9) are stacked by means of the method in Patent Document 1 may be considered. In this case, setting the thickness of the zirconium oxide film which has a large dielectric constant to be greater than the thickness of the aluminum oxide film makes it possible to achieve a smaller EOT in comparison with the same physical thickness. If the film thickness of aluminum oxide is set at 0.5 nm as the minimum thickness described in Patent Document 1, the EOT of aluminum oxide is around 0.22 nm. If the remaining physical film thickness of 4.5 nm is formed by zirconium oxide having a dielectric constant of 25, the EOT of the zirconium oxide portion is approximately 0.70 nm. This means that the EOT of the stacked dielectric film comprising aluminum oxide and zirconium oxide is 0.92 nm so it is not possible to satisfy the target EOT of 75 nm or less. Even if the film thickness of aluminum oxide were set at zero and a dielectric film (5 nm) comprising a single film of zirconium oxide having a dielectric constant of 25 were produced, the EOT would still be 0.78 nm and the target would not be satisfied.

In Patent Document 2, a layered film in which an ALD-ZrO film, an ALD-AlO film and an ALD-TiO film are stacked in succession is employed as a dielectric film 30 forming part of a capacitor. It could be expected that using a TiO film having a high dielectric constant would make it possible to reduce the EOT of the capacitor. However, Patent Document 2 does not describe any detailed conditions governing the characteristics of the capacitor, such as the thickness and crystallinity of each film, or the heat-treatment temperature etc. It is only the conditions under which the abovementioned films are formed using the semiconductor production apparatus depicted in that invention which are described. The characteristics of the capacitor which is formed are therefore unclear. As is well known, a TiO film forms either a rutile crystal structure or an anatase crystal structure at the crystallization stage. The rutile crystal structure exhibits a very high dielectric constant of 80 or greater, but the anatase crystal structure exhibits a dielectric constant of only around 40. A normal titanium oxide film shifts to a rutile crystal structure via an anatase crystal structure in the crystallization process, and a temperature of 700° C. or greater is required for the shift to the rutile crystal structure. As indicated in Patent Document 6 filed by the present inventors, a TiO film does not readily crystallize to a rutile crystal structure at low temperature unless the TiO film is formed on a material in which at least the base is formed by a predetermined crystal structure. In the capacitor described in Patent Document 2, a TiO film is formed on an AlO film which is a very stable amorphous insulating film, and even if heat treatment is carried out in this state, it is still difficult to produce a TiO film having a rutile crystal structure.

In Patent Document 1 mentioned above, it is necessary to reduce the thickness of the AlO film and the ZrO film and to increase the dielectric constant by crystallizing the ZrO film in order to achieve a small EOT. However, according to experiments carried out by the present inventors, when the thickness of the dielectric in the capacitor described in Patent Document 1 is reduced, the ZrO film does not readily crystallize and it is not possible to reduce the EOT. Furthermore, heat treatment is required at a higher temperature and for a longer time in order to crystallize the ZrO film when it has been thinned, and there are problems in that heat resistance is insufficient and the leakage current increases. As a result of various investigations carried out by the present inventors into measures for avoiding these problems, it was found that it is effective to provide a protective film comprising a TiO film between the dielectric film and the upper electrode and between the lower electrode and the dielectric film, as described in Patent Documents 3-5.

For example, when the technology described in Patent Document 4 or Patent Document 5 is employed, it is possible to impart to a ZrO film a dielectric constant that could not be achieved with the method in Patent Document 1, and also to impart thermal stability. That is to say, investigations carried out by the present inventors showed that it is possible to achieve a dielectric constant of 32-38 when a TiO film having a thickness of 0.4 nm or greater is formed on the lower electrode, a ZrO film is further formed in such a way that the film thickness is 4 nm or greater, and AlO contained therein as an impurity is present at an Al concentration of around 0-10% expressed as Al/(Al+Zr), for example. This results from the fact that the ZrO film is formed after the TiO film has been formed on the lower electrode, whereby the crystallinity of the ZrO film is improved and the density is increased and therefore the proportion of tetragonal crystals having a high dielectric constant is increased, as also described in Patent Document 4. Test calculations similar to those carried out in relation to Patent Document 1 showed that when a zirconium oxide film having a dielectric constant of 38 is used, the EOT is around 0.51 nm if the physical film thickness is 5 nm, which is the required minimum limit for suppressing tunneling current. This satisfies the target EOT of 0.75 nm. Meanwhile, a considerable reduction in leakage current is also confirmed in an evaluation based on a test element group (TEG) formed by a flat capacitor and a small number of three-dimensional capacitors etc.

As described above, in Patent Documents 3, 4 and 5, a second protective film comprising titanium oxide is disposed between a lower electrode and a dielectric, and a first protective film comprising titanium oxide is disposed between a dielectric and an upper electrode. The effect of the second protective film and the first protective film described in Patent Documents 3, 4 and 5 will be summarized below.

First of all, the second protective film has the effect of improving adhesion between the dielectric film and the lower electrode and preventing peeling of the dielectric film which would cause a defect, while also improving the crystallinity of the zirconium oxide dielectric film, thereby increasing the dielectric constant. For example, Patent Document 1 indicates that when zirconium oxide is formed directly on titanium nitride, the dielectric constant of the zirconium oxide film is 20-25. Investigations carried out by the present inventors also confirmed that this could be substantially reproduced. This would suggest that the dielectric film is in an amorphous state or a cubic crystal state with a low dielectric constant, or a mixture of these states. Meanwhile, experiments carried out by the present inventors showed that it is readily possible to achieve a dielectric constant of 32-38 when a second protective film comprising titanium oxide is formed on the lower electrode, after which a dielectric film comprising zirconium oxide as the main component is formed, as described in Patent Document 4 and Patent Document 5.

This would suggest that the second protective film has an effect of promoting crystallization of zirconium oxide and growth of crystal grains thereof.

Table 1 below shows the results of a comparison of peak intensity in X-ray diffraction (XRD) when a second protective film (titanium oxide film on the lower electrode) is present and when it is absent, in regard to a zirconium oxide film having a thickness of 6.6 nm. It should be noted that these results reproduce the results before and after annealing shown in Table 1 of Patent Document 4 (with the rate of change of Sample 1 having been corrected). Sample 1 has a structure in which a zirconium oxide film comprising about 3 at. % AlO and a first protective film comprising TiO having a thickness of 1 nm are formed in succession on a lower electrode comprising a TiN film having a thickness of 10 nm, while sample 2 has a structure in which a TiO film having a thickness of 0.5 nm is formed as a second protective film between the lower electrode and the zirconium oxide film in the structure of Sample 1 (see FIG. 18 of Patent Document 4). As shown in FIG. 16 of Patent Document 4, the diffraction peak intensity is greater immediately after film formation (“as deposition”) in Sample 2 in which the second protective film is present, indicating good crystallinity. Furthermore, as shown in FIG. 17 of Patent Document 4, even after annealing at 450° C. for 6 hours (N₂ atmosphere), Sample 2 in which the second protective film is present still demonstrates a large peak. That is to say, it is clear that the presence of the second protective film means that the zirconium oxide film exhibits better crystallinity in comparison with a case in which the second protective film is not present on the lower electrode.

TABLE 1

| | Diffraction peak intensity | | |
|---|---|---|---|
| | A: before | | Rate of change |
| | annealing | B: after annealing | (B/A) |
| Sample 2 | 0.87 | 1.00 | 1.15 |
| Sample 1 | 0.25 | 0.59 | 2.36 |

Furthermore, the rate of change in the peak intensity before and after annealing is 2.36 in Sample 1 and 1.15 in Sample 2. The rate of change is smaller when the second protective film is present, so there is less change in crystallinity; in other words, it can be anticipated that the volume shrinkage caused by the thermal load (to be described later) from immediately after film formation until formation of the upper electrode will be reduced. According to Patent Document 4, this can be cited as one reason for which the presence of the second protective film affords greater resistance to the thermal load from formation of the upper electrode and onward.

Meanwhile, the first protective film serves as a stress-alleviating layer and has an effect such that cracks or pin holes are less likely to be formed in the dielectric film, and also has an effect such that even if cracks or pin holes are formed, the surfaces of the cracks or pin holes are less likely to be exposed when the upper electrode is formed, as with the technique of “internal penetration” which is used in glasswork and the like. As a result, it is possible to restrict the penetration of cracks and pin holes into the upper electrode, and it is possible to restrict short-circuit states between the upper electrode and the lower electrode of the capacitor. Furthermore, the presence of the first protective film means that the dielectric film is no longer exposed to a reducing atmosphere or a corrosive atmosphere when the upper electrode is directly formed, and therefore it has the effect of making it possible to avoid problems in terms of oxygen deficiency and problems in terms of the dielectric film itself being etched.

For example, the upper electrode made of titanium nitride is formed by means of known CVD or ALD at a processing temperature of between 350° C. and 450° C. Before the film is formed, a substrate is normally conveyed to a reaction chamber of a film formation apparatus, the temperature is raised to the processing temperature and then held until the substrate temperature is stable. After this, starting material gases are introduced into the reaction chamber in a predetermined sequence and film formation is started. Titanium tetrachloride (TiCl₄) and ammonia (NH₃) are used as starting material gases, and in this case HCl, Cl₂, H₂, N₂, NH₄Cl and the like are produced in the atmosphere as by-products.

Here, a description will be given of a case in which the upper electrode is formed without the first protective film being provided. FIG. 1 illustrates a case in which a second protective film 1002 comprising TiO is formed on a lower electrode 1001, and a dielectric 1003 comprising a ZrO film containing an Al-doped layer 1003a is formed in succession thereon, after which an upper electrode 1004 is formed in the manner described above, without a first protective film being provided. During the retention time for processing temperature stabilization which is required before the upper electrode (TiN) 1004 is formed, growth of crystal grains of the dielectric film 1003 is promoted by the thermal load, and cracks and pin holes 1005 are formed in the dielectric film 1003 due to volume shrinkage of the dielectric film 1003 accompanying said growth. If the upper electrode 1004 is formed while cracks and pin holes are present in the dielectric film 1003, part of the upper electrode 1004 ends up embedded within the cracks and pin holes 1005. The second protective film 1002 comprising a thin layer of TiO has virtually no function as a dielectric film and as a result the capacitor is virtually in a short-circuit state and the function thereof can no longer be fulfilled. Furthermore, even at the level at which cracks and pin holes do not constitute a problem, the dielectric film 1003 exposed to the TiN film formation atmosphere is subject to damage such as etching and oxygen deficiency 1006, and the leakage current increases. This problem is avoided in Patent Document 3-5 by providing the first protective film.

However, if the capacitor in Patent Document 4 or Patent Document 5 having the effect of reducing the EOT and reducing leakage current is applied to a gigabit-order product comprising a three-dimensional structure, minority defects in cell units may be observed in evaluation tests under a high-temperature working environment. These minority defects are caused by minute leaks mediated by defects in the dielectric film. If a large leakage current is caused by the defects, it is easily possible to distinguish conforming and nonconforming articles by means of a TEG-based I-V characteristic evaluation, but if the leakage current is very small, it is difficult to distinguish conforming and nonconforming articles using a TEG-based evaluation method in a flat capacitor. Furthermore, even in the case of a three-dimensional structure, averaging occurs with a method in which the leakage current is measured by consolidating several tens of thousands of cells, and observation is still difficult. That is to say, defects accompanying very slight leakage are difficult to distinguish using a flat capacitor and a TEG-based evaluation method, and such defects are observed for the first time as minority defects in cell units under a working environment at a higher temperature than room temperature after application to a product/mounting on a product.

According to investigations carried out by the present inventors, it has been established that it may not be possible to adequately restrict these minority defects even if the method described in Patent Document 4 or Patent Document 5 is employed. In particular, there are times when these defects are manifested as cells having a short memory retention time in evaluation tests in which the device working temperature exceeds 90° C. Cells deemed to be defective in an evaluation test are replaced in the electronic circuit with regular cells which are prepared as a reserve for redundancy. However, the reserve cells are also limited and are also used for replacing defective cells from other modes, so the formation of minority defects ultimately causes a deterioration in the overall yield and there is room for improvement.

### Means for Solving the Problems

In the light of the abovementioned problems, a semiconductor device according to a mode of embodiment of the present invention is characterized in that it comprises a capacitor provided with:

a lower electrode disposed on a semiconductor substrate;
a second protective film which covers at least the surface of the lower electrode;
a dielectric film which covers the surface of the second protective film and has a defect which develops in the film thickness direction from an upper surface opposite the second protective film;
a third protective film having at least a defect-filling film comprising an insulator which fills the defect and is different from the main component of the dielectric film;
a first protective film which covers the dielectric film and the third protective film; and
an upper electrode which covers the first protective film.

### Advantage of the Invention

By virtue of the semiconductor device according to the present invention, even if a defect such as a crack is already formed in the dielectric film at a stage before the first protective film is formed, the third protective film having a defect-filling film comprising an insulator which fills the defect is provided, and as a result it is possible to avoid minority defects caused by leakage current.

### BRIEF DESCRIPTION OF THE FIGURES

FIG. 1 is a schematic view in cross section showing the layered structure of a capacitor to illustrate the problems in the prior art in which a first protective film is not formed;

FIG. 2 illustrates the layered structure of a sample employed in an experimental example;

FIG. 3 shows analysis results of X-ray diffraction waveforms obtained by means of XRD of an “as depo.” film immediately after film formation in Sample 1 in which the thickness of a ZrOx film is 2 nm in the sample of FIG. 2, and annealed films which have been annealed at the temperatures shown in the drawing;

FIG. 4 shows analysis results of X-ray diffraction waveforms obtained by means of XRD of an “as depo.” film immediately after film formation in Sample 2 in which the thickness of the ZrOx film is 4 nm in the sample of FIG. 2, and annealed films which have been annealed at the temperatures shown in the drawing;

FIG. 5 shows analysis results of X-ray diffraction waveforms obtained by means of XRD of an “as depo.” film immediately after film formation in Sample 3 in which the thickness of the ZrOx film is 5 nm in the sample of FIG. 2, and an annealed film which has been annealed at the temperature shown in the drawing;

FIG. 6 shows an SEM image of the surface of a sample in which a zirconium oxide film having a thickness of 6 nm is formed by ALD on a titanium oxide film;

FIG. 7 is a schematic view in cross section showing the layered structure of a capacitor to illustrate the problems of the prior art in which a first protective film is formed;

FIG. 8 is a schematic view in cross section showing the layered structure of a capacitor according to a first exemplary embodiment of the present invention;

FIG. 9 is a plan view showing an example of the layout of a DRAM memory cell according to an exemplary embodiment of the present invention;

FIG. 10 is a view in cross section corresponding to the line A-A′ in the plan view of FIG. 9;

FIG. 11-1 is a process diagram in cross section of a semiconductor device corresponding to FIG. 10;

FIG. 11-2 is a process diagram in cross section of a semiconductor device corresponding to FIG. 10;

FIG. 12 is an ALD flowchart for a case in which a dielectric film 603 and a third protective film 604 are continuously formed;

FIG. 13 is a diagram showing the results of a comparative evaluation of the relationship between leakage current density J (A/cell) and equivalent oxide thickness EOT (nm) for a conventional capacitor and a capacitor having a TAZT structure according to an exemplary embodiment of the present invention;

FIG. 14 is a diagram showing the results of a comparison of the cumulative frequency distribution of the data retention time for a conventional DRAM and a DRAM according to an exemplary embodiment of the present invention;

FIG. 15 is a schematic view in cross section showing the layered structure of a capacitor according to a second exemplary embodiment of the present invention;

FIG. 16 is a schematic view in cross section showing the layered structure of a capacitor according to a third exemplary embodiment of the present invention;

FIG. 17 is a schematic view in cross section showing the layered structure of a capacitor according to a fourth exemplary embodiment of the present invention; and

FIG. 18 is a schematic view in cross section showing the layered structure of a capacitor according to a fifth exemplary embodiment of the present invention.

### MODE OF EMBODIMENT OF THE INVENTION

Experimental examples carried out by the present inventors will be described below with the aid of FIG. 2-FIG. 5 before a first mode of embodiment is described.

### EXPERIMENTAL EXAMPLES

In order to guard against the abovementioned minority defects, the present inventors carried out various experimental investigations, as a result of which it was found that a zirconium oxide film constituting a dielectric film is already crystallized at the stage immediately after film formation (“as deposition”; referred to below as “as depo.”). The present inventors first of all investigated the film thickness dependency of crystallinity in regard to a zirconium oxide film.

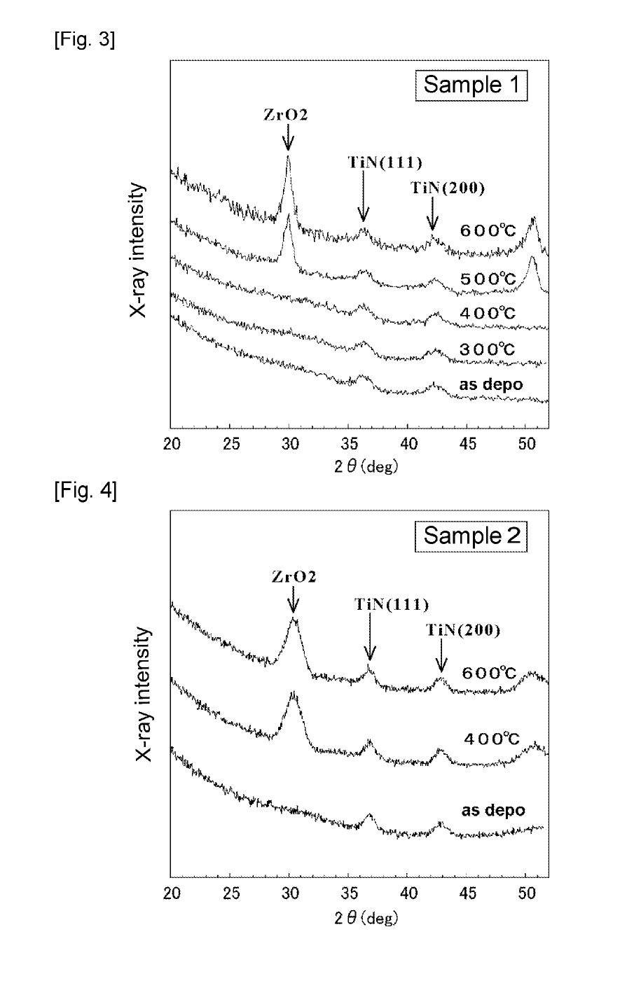

FIG. 2 illustrates the layered structure of a sample where a TiN film 2001 having a thickness of 10 nm is formed as a lower electrode on a Si substrate 2000, a second protective film 2002 comprising a titanium oxide film having a thickness of 0.5 nm is formed thereon, and a zirconium oxide film 2003 is further formed on the second protective film 2002; the thickness of the zirconium oxide film 2003 is 2 nm (Sample 1), 4 nm (Sample 2) or 5 nm (Sample 3). Furthermore, FIG. 3-5 show analysis results of X-ray diffraction waveforms obtained by means of XRD (X-ray diffraction) of an “as depo.” film immediately after film formation for each sample, and annealed films which were annealed at the temperatures shown in the drawings. The signal intensity was small according to normal XRD for Sample 1, so the result obtained by observation using in-plane-XRD which has higher sensitivity is shown. It should be noted that the zirconium oxide film is formed using ALD with cyclopentadienyl tris(dimethylamino)zirconium as a precursor.

It can be seen from the results in FIG. 3-5 that the zirconium oxide films in Sample 1 (2 nm) and Sample 2 (4 nm) are in an amorphous or microcrystalline state and an XRD diffraction peak is apparent for the first time after annealing, whereas the zirconium oxide film of Sample 3 (5 nm) already has a diffraction peak as depo., despite the fact that the film formation temperature is a low temperature of 250° C. That is to say, it is clear that crystallization and growth of crystal grains proceed rapidly while the film thickness increases from 4 nm to 5 nm in the process of forming the zirconium oxide film. It should be noted that the as depo. sample having a film thickness of 4 nm is also measured using in-plane-XRD, but a crystal peak in the zirconium oxide film is not observed.

When crystallization proceeds and crystal grains grow while an amorphous or microcrystalline zirconium oxide film at 4 nm or less grows to a thickness of 5 nm, there is accompanying volume shrinkage, and therefore it is speculated that defects such as cracks and pin holes are already formed in the surface thereof before the first protective film is formed, even though these are not to the extent produced as a result of the thermal load (350° C.-450° C.) when the upper electrode is formed.

Surface observation of the dielectric film after film formation is then attempted using a scanning electron microscope (SEM).

FIG. 6 shows an SEM observation at a magnification of 100 000 times of the surface of a sample in which a TiN surface is oxidized by means of heat treatment under an ozone (O₃) atmosphere on a TiN film having a thickness of 10 nm formed on a Si substrate, and a titanium oxide film constituting a second protective film is further formed by means of known ALD, after which a zirconium oxide film having a thickness of 6 nm is formed on the titanium oxide film by means of ALD.

It can be confirmed from the results of FIG. 6 that cracks are already formed in the surface of the zirconium oxide film immediately after film formation.

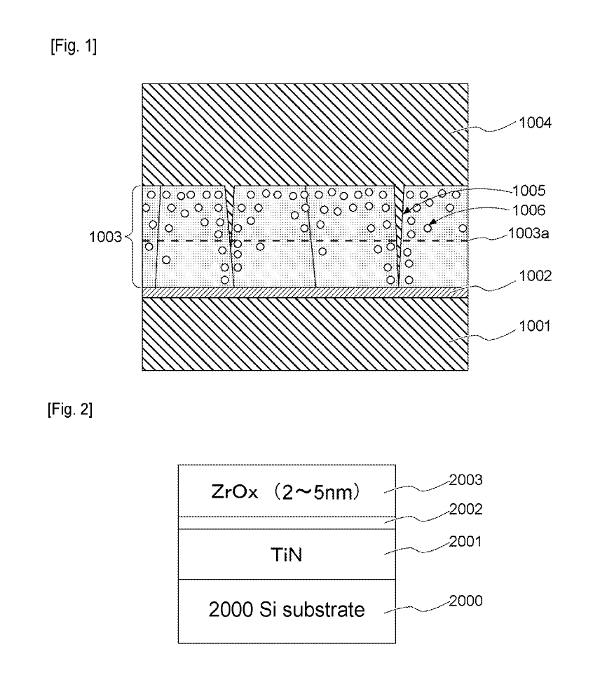

If the titanium oxide film of the first protective film is formed while cracks have been produced in this way, it is speculated that the titanium oxide film will fill the cracks formed in the surface of the zirconium oxide film, as described in Patent Documents 3-5. FIG. 7 shows a situation in which the first protective film is formed, based on the results of FIG. 6, as described in Patent Documents 3-5. When a second protective film 502 comprising a titanium oxide film is formed on a lower electrode 501 and a dielectric film 503 comprising a zirconium oxide film is formed thereon in an effort to increase the dielectric constant of the zirconium oxide film 503, crystallization and crystal grain growth proceed rapidly while the zirconium oxide film 503 grows from 4 nm to 5 nm, and defects such as cracks 506 and pin holes are already present in the zirconium oxide film immediately after film formation. A titanium oxide film constituting a first protective film 504 is formed in this state, and therefore part of the first protective film 504 is thought to penetrate the cracks 506. It should be noted that the first protective film 504 is formed, so even if an upper electrode 505 comprising a TiN film is subsequently formed, damage such as the oxygen deficiency 1006 shown in FIG. 1 and etching does not arise.

Titanium oxide films are known as dielectric films having a high dielectric constant, while at the same time it is also well known that such films are also used as oxide semiconductors. As described in Patent Document 4, titanium oxide of 1 nm or greater behaves as a conductor, and a titanium oxide film still behaves as a semiconductor when the thickness thereof is reduced, so the present inventors believe that the titanium oxide film serving as the first protective film 504 which fills the cracks 506 in the dielectric film forms a minute leak path at the device working temperature which is higher than room temperature, although not to the extent of a short-circuit state which occurs when a titanium nitride conductor penetrates the cracks, and as a result minority defects are produced in cell units. That is to say, crystallization of the zirconium oxide film 503 is promoted by the presence of the titanium oxide film constituting the second protective film 502, and as a result it is believed that this also promotes crack formation.

The semiconductor device according to the present invention is characterized in that it comprises a capacitor provided with: a lower electrode disposed on a semiconductor substrate; a second protective film which covers at least the surface of the lower electrode; a dielectric film which covers the surface of the second protective film and has a defect which develops in the film thickness direction from an upper surface opposite the second protective film; a third protective film having at least a defect-filling film comprising an insulator which fills the defect and is different from the main component of the dielectric film; a first protective film which covers the dielectric film and the third protective film; and an upper electrode which covers the first protective film.

A “dielectric” is generally described in terms of the dielectric constant in the film thickness direction and an “insulator” is generally described in terms of the insulating properties as a material, and the two may indicate the same material. Furthermore, there are also materials which have a high dielectric constant on the one hand while also demonstrating conductor or semiconductor characteristics on the other hand, such as the abovementioned titanium oxide. According to the present invention, the insulator forming the defect-filling film included in the third protective film does not particularly require a high dielectric constant but it does require high insulating properties. On the other hand, the dielectric forming the dielectric film must have a relatively high dielectric constant which is preferably 25 or greater and more preferably 30 or greater. Furthermore, when a plurality of lower electrodes are covered, as with a DRAM (to be described later), the dielectric film preferably has predetermined insulating properties such that short-circuiting does not occur between the lower electrodes. A material different from the main component of the dielectric film (e.g. zirconium oxide) is normally used for the insulator forming the defect-filling film. The insulator forming the defect-filling film is preferably a material having a higher crystallization temperature than the main component of the dielectric film, and more preferably said insulator is an amorphous material which does not crystallize even when the first protective film and the upper electrode are subsequently formed. In the third protective film, the defect-filling film which fills the defect that develops in the film thickness direction has substantially no effect by itself on the dielectric constant of the dielectric film, but it should be noted that a film which is deposited on the surface of the dielectric film when the defect-filling film is formed (referred to below as the “planar protective film”) does have an effect on the dielectric constant in the film thickness direction.

Furthermore, the dielectric film has defects which develop in the film thickness direction from an upper surface opposite the second protective film. These defects are cracks or pin holes etc. which are apparent at the surface of the dielectric film after it has been formed, said defects extending from the upper surface toward the film thickness direction (the direction of the second protective film). This is due to the fact that volume shrinkage accompanying crystallization of the dielectric film during film formation or after film formation is greater on the free upper surface side than on the lower surface side which is fixed by the second protective film. According to the present invention, the crystallinity of the dielectric film has especially good continuity from the upper surface as far as the lower surface, and these defects which occur in multiple locations at the grain boundary also develop and extend from the upper surface up to the lower surface or to the vicinity of the lower surface.

Materials equivalent to those of the first protective film and the second protective film described in Patent Document 4 may be used as the first protective film and the second protective film according to the present invention, but titanium oxide films are preferred.

Exemplary embodiments of the present invention will be described through specific examples below.

### First Exemplary Embodiment

### Semiconductor Device

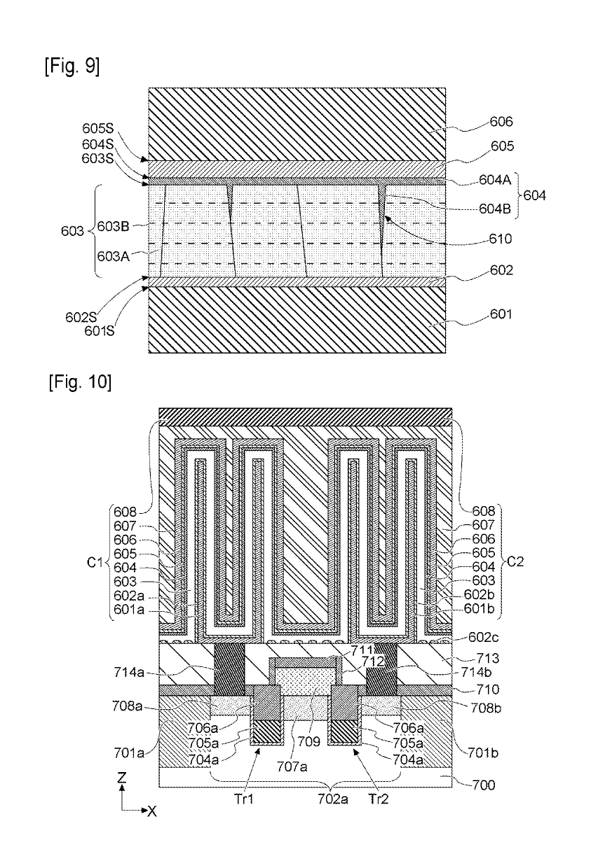

According to this exemplary embodiment, a semiconductor device constituting a dynamic random access memory (DRAM) will be described as one example. However, the present invention is not limited to a DRAM and it may equally be applied to semiconductor devices in general in which a capacitor is mounted. The semiconductor device according to this exemplary embodiment will be described below with the aid of FIG. 8, FIG. 9 and FIG. 10. FIG. 8 is an enlarged view in cross section inside capacitors C1, C2 illustrated in the cross-sectional view of a DRAM memory cell shown in FIG. 10, where part of the film structure located between a lower electrode and an upper electrode has been extracted. FIG. 9 is a plan view showing an example of the layout of the DRAM memory cell. Furthermore, FIG. 10 is a view in cross section corresponding to the line A-A′ in the plan view of FIG. 9.

A semiconductor device having capacitors according to this exemplary embodiment will be described first of all with the aid of FIG. 9 and FIG. 10.

The layout of the DRAM memory cell will be described first with the aid of the plan view in FIG. 9. It should be noted that a DRAM normally includes a peripheral circuit region for driving the memory cells but this is omitted from FIG. 9. A plurality of first element isolation regions 730 (730a, 730b, 730c) extending in the X′-direction (first direction) and a plurality of second element isolation regions 701 (701a, 701b) extending in the Y-direction (second direction) are disposed on the surface of a semiconductor substrate comprising p-type single-crystal silicon, for example. As a result, a first active region 702a is provided, the periphery thereof being surrounded by the first element isolation regions 730a, 730b and by the second element isolation regions 701a, 701b. Furthermore, a second active region 702b is provided, the periphery thereof being surrounded by the first element isolation regions 730b, 730c and by the second element isolation regions 701a, 701b. The second active region 702b is adjacent to the first active region 702a with the first element isolation region 730b therebetween. Two trenches extending in the Y-direction are disposed in such a way as to divide the first and second active regions 702a, 702b extending in the X′-direction into three, and a first gate electrode 705a and a second gate electrode 705b which fill the trenches are provided. The gate electrodes are arranged across the plurality of active regions which are arrayed in the Y-direction, and form word lines of the DRAM.

The first active region 702a and the second active region 702b have the same structure and the following description will therefore focus on the first active region 702a. By providing the two gate electrodes 705a, 705b, the first active region 702a is divided into a first capacitance diffusion layer 708a, a bit line diffusion layer 707a, and a second capacitance diffusion layer 708b. A first transistor Tr1 is formed by the capacitance diffusion layer 708a, the first gate electrode 705a and the bit line diffusion layer 707a. Furthermore, a second transistor Tr2 is formed by the second capacitance diffusion layer 708b, the second gate electrode 705b and the bit line diffusion layer 707a. The first capacitor C1 is disposed on the first capacitance diffusion layer 708a and the second capacitor C2 is disposed on the second capacitance diffusion layer 708b. Furthermore, a bit line 709 extending in the X-direction (third direction) is disposed on the bit line diffusion layer 707a which is shared by the first transistor Tr1 and the second transistor Tr2. The second active region 702b has the same structure and comprises a third capacitor C3 on a third capacitance diffusion layer 708c, a fourth capacitor C4 on a fourth capacitance diffusion layer 708d, and a bit line 609 on a bit line diffusion layer 707b.

Reference will now be made to the cross section of FIG. 10. The DRAM according to this exemplary embodiment comprises the buried gate electrode-type cell transistors Tr1, Tr2. That is to say, the gate electrodes 705a, 705b constituting word lines are buried inside a semiconductor substrate 700. In this configuration the bit line 709 is disposed on the upper surface of the semiconductor substrate 700, and the capacitors C1 and C2 are disposed above the bit line 709 with capacitance contact plugs 714a, 714b interposed. The first transistor Tr1 comprises: a gate insulating film 704a which covers the inner surface of a gate trench 703 disposed inside the semiconductor substrate 700, a gate electrode 705a which fills the lower part of the gate trench 703 with the gate insulating film 704a interposed, the first capacitance diffusion layer 708a, and the bit line diffusion layer 707a. The second transistor Tr2 also has the same structure. The bit line 709 which is connected above the bit line diffusion layer 707a is provided running through a first interlayer insulating film 710 disposed on the semiconductor substrate 700. The first capacitance contact plug 714a and the second capacitance contact plug 714b are provided running through a second interlayer insulating film 713 disposed in such a way as to cover the bit line 709, and crown-type first and second lower electrodes 601a, 601b connected to the upper surface of the respective capacitance contact plugs are provided. Second protective films 602a, 602b comprising titanium oxide and formed by a continuous film are disposed on the surface of the first lower electrode 601a and the second lower electrode 601b. Moreover, the second protective film 602 formed on the surface of the lower electrode 601 is also formed on the upper surface of the second interlayer insulating film 713 as island-like second protective films 602c which are isolated from each other. A dielectric film 603, a third protective film 604, a first protective film 605, an upper electrode 606, a trench-filling upper electrode 607 and a plate electrode 608 are stacked in succession in such a way as to cover the second protective film 602. It should be noted that FIG. 10 relates to an example of a crown-type capacitor structure but this is not limiting and a cylindrical capacitor is equally feasible. In addition, a support structure may also be included between adjacent capacitors in order to avoid the problem of capacitors collapsing because of miniaturization.

The capacitor configuration will be described next with the aid of FIG. 8. The capacitor according to this exemplary embodiment chiefly comprises: the lower electrode 601; the second protective film 602 which is at least in contact with the lower electrode 601 and covers an upper surface 601S thereof; the dielectric film 603 which is in contact with the second protective film 602, covers an upper surface 602S thereof and has cracks (defects) 610 extending in the film thickness direction; the third protective film 604 which includes at least a defect-filling film 604B that fills the defects and comprises an insulating film; the first protective film 605 which covers the dielectric film 603 and the third protective film 604; and the upper electrode 606 which is in contact with the first protective film 605 and covers a surface 605S thereof.

In the configuration of FIG. 8, the third protective film 604 further comprises a planar protective film 604A which is in contact with the upper surface of the defect-filling film 604B while also being in contact with the dielectric film 603 and covering an upper surface 603S (the surface opposite the second protective film 602) thereof. In this case, the first protective film 605 covers the dielectric film 603 with the planar protective film 604A interposed. It should be noted that the planar protective film 604A does not necessarily have to be a continuous film; the upper surface 603S of the dielectric film 603 may also be partially exposed, in which case the first protective film 605 may come into partial contact with the dielectric film 603.

To describe this from another point of view, the semiconductor device according to this exemplary embodiment comprises: the lower electrode 601 which is disposed on the semiconductor substrate 700; the second protective film 602 which is at least in contact with the lower electrode 601 and covers the upper surface 601S; the dielectric film 603 which is in contact with the second protective film 602, covers the upper surface 602S thereof and has cracks (defects) 610 extending in the film thickness direction; the third protective film 604 comprising an insulator which is different from the main component of the dielectric film 603; the first protective film 605 which is in contact with the third protective film 604 and covers an upper surface 604S thereof; and the upper electrode 606 which is in contact with the first protective film 605 and covers the upper surface 605S thereof, the third protective film 604 comprising the planar protective film 604A which is located on the upper surface 603S of the dielectric film 603, and the defect-filling film 604B which is in contact with one surface (the surface on the lower electrode side) of the planar protective film 604A and projects from the planar protective film 604A in such a way as to fill the cracks 610.

This configuration will be described in further detail. The lower electrode 601 comprises a titanium nitride (TiN) film. The second protective film 602 which is in contact with the lower electrode 601 and is provided in such a way as to cover the upper surface 601S comprises a titanium oxide film. The thickness of the second protective film 602 is preferably in the range of 0.4-2.0 nm and more preferably in the range of 0.5-1.0 nm. As shown in FIG. 10, the second protective film 602 forms a continuous film at the portion in contact with the upper surface 601S of the lower electrode 601, but it is separated into islands above the second interlayer insulating film 713 located between adjacent capacitors.

The dielectric film 603 which is in contact with the second protective film 602 and is disposed in such a way as to cover the upper surface 602S is formed by a zirconium oxide film 603A having at least one impurity-doped layer 603B within the dielectric film 603. The surface density of impurity atoms in one layer of the impurity-doped layer is preferably less than 1.4 E+14 (atoms/cm²), and more preferably no greater than 1.0 E+14 (atoms/cm²). Aluminum (Al) and silicon (Si) etc. may be cited as impurity atoms, but Al is preferred. Furthermore, the concentration of impurity atoms contained in the dielectric film 603 formed by a zirconium oxide (ZrO) film is such that M is between 0.2 and 2%, expressed as M/(Z+M) where Z is the number of zirconium atoms and M is the number of impurity atoms. It should be noted that metal atoms such as Al and Si which form the third protective film are not included in the concentration of impurity atoms. Meanwhile, the concentration of zirconium atoms when the dielectric film and the third protective film are combined is preferably at least 80%, and more preferably at least 90%, in terms of the ratio of the number of atoms expressed as Z/(Z+M′), where M′ is the number of metal atoms excluding zirconium. The abovementioned value of 0.2 to 2% means a state in which impurity molecules such as aluminum oxide (AlO) molecules are scattered within the plane of the zirconium oxide film without the impurity-doped layer 603B forming a continuous film. A case in which Al is introduced as impurity atoms will be described below, where the impurity-doped layer 603B is an Al-doped layer 603B. The zirconium oxide film 603A positioned vertically either side of the Al-doped layer 603B therefore makes contact in regions where the AlO molecules are not scattered, and crystal growth of the zirconium oxide film 603A proceeds simultaneously while spatial continuity is maintained over the whole of the dielectric film 603. That is to say, the Al-doped layer 603B does not inhibit crystal growth of the zirconium oxide film 603A.

On the other hand, the aluminum oxide film in the capacitor having a TZAZT structure illustrated in FIG. 10 of Patent Document 4 mentioned above does inhibit crystal growth of the zirconium oxide film. TZAZT means a structure comprising the following: titanium oxide film (T)/zirconium oxide film (Z)/aluminum oxide film (A)/zirconium oxide film (Z)/titanium oxide film (T). The aluminum oxide film used in Patent Document 4 is an aluminum oxide film in which AlO molecules are present as a continuous film, rather than the Al-doped layer according to this exemplary embodiment in which the AlO molecules are isolated. In the capacitor having a TZAZT structure described in Patent Document 4, the zirconium oxide film positioned vertically either side of the aluminum oxide film is completely separated by the aluminum oxide film, and continuity of crystal growth cannot be maintained. That is to say, the aluminum oxide film used in Document 4 is a factor in the inhibition of crystal growth of the zirconium oxide film. This means that there is a difficulty in achieving a high dielectric constant with a TZAZT structure.

Returning to the description of FIG. 8, the thickness T1 of the dielectric film 603 is preferably such that the total thickness Td including the thickness T2 of the planar protective film 604A of the third protective film 604 (to be described later) is between 5 nm and 7 nm, and more preferably between 5.3 nm and 6 nm. In this exemplary embodiment, the thickness T1 of the dielectric film 603 is 5.0 nm.

The dielectric film 603 having a thickness of 5.0 nm is disposed on the second protective film 602 and therefore the cracks 610 are formed while the dielectric is being formed, as described above.

The third protective film 604 which is disposed in contact with the dielectric film 603 in such a way as to cover the upper surface 603S thereof is formed by an insulating film such as an aluminum oxide film, a silicon dioxide film or a silicon nitride film. The third protective film 604 is provided in such a way as to produce a formed film thickness of at least 0.1 nm on the upper surface 603S of the dielectric film 603. This normally corresponds to two or more cycles of ALD. Furthermore, the thickness of the formed film is preferably at least 0.2 nm and more preferably at least 0.3 nm. In this case the thickness is approximately 0.3 nm. The effect of filling cracks 610 formed in the dielectric film 603 when the third protective film 604 is thinner than 0.1 nm is not adequately demonstrated. On the other hand, the planar protective film 604A affects the dielectric constant in the film thickness direction so if the film thickness is greater it becomes difficult to maintain the capacitance of the capacitor at a permitted value. A film thickness which ensures that capacitance in the permitted range is satisfied is therefore preferred. When aluminum oxide is formed as the third protective film, the thickness of the planar protective film 604A is therefore 1.0 nm or less, preferably 0.6 nm or less and more preferably 0.5 nm or less. It should be noted that the formed film thickness and the planar protective film 604A thickness do not necessarily have to be the same, and it is possible to form a film up to a thickness adequate for correcting defects and then to reduce this to a thickness permitted for the planar protective film 604A. Furthermore, it is not essential for the defect-filling film 604B to completely fill the defects (cracks etc.); provided that it is possible to prevent the formation of a leak path due to the first protective film penetrating into the defects, a state in which the defect-filling film 604B does not completely fill the defects is acceptable. For example, a gap may be left to the extent that the Ti precursor for forming the first protective film cannot penetrate.

As shown in FIG. 8, the third protective film 604 comprises: the planar protective film 604A which is positioned in contact with the upper surface 603S of the dielectric film 603; and the defect-filling film 604B which is in contact with the planar protective film 604A and projects from the rear surface of the planar protective film 604A in such a way as to fill the cracks 610. Furthermore, the third protective film 604 according to this exemplary embodiment is such that the defect-filling film 604B and the planar protective film 604A are insulating films which are formed in the same process and comprise the same material. This is not limiting, however, and they may be insulating films comprising the same material formed in separate processes, as will be described later. In addition, they may equally be insulating films comprising different materials formed in separate processes.

The first protective film 605 which is disposed in contact with the third protective film 604 in such a way as to cover the upper surface 604S thereof is formed by a titanium oxide film. The thickness of the first protective film 605 is preferably in the range of 0.4-3.0 nm and more preferably in the range of 0.5-1.0 nm. The thickness in this case is 0.6 nm.

The upper electrode 606 which is in contact with the first protective film 605 and is disposed in such a way as to cover the upper surface 605S thereof is formed by a titanium nitride film. The thickness of the upper electrode 606 is preferably 4 nm-10 nm. The thickness in this case is 7 nm.

As mentioned above, the capacitor according to this exemplary embodiment comprises the following elements which are stacked in succession, namely: the lower electrode 601, the second protective film 602, the dielectric film 603, the third protective film 604, the first protective film 605, and the upper electrode 606. On the other hand, in a structure in which the capacitor structure according to this exemplary embodiment is simply vertically inverted, the insulator such as the aluminum oxide film forming the third protective film 604 essentially does not act to promote crystal grain growth or crystallization of the zirconium oxide film forming the dielectric film 603. It is therefore difficult to form a dielectric film 603 having a high dielectric constant. Even if the dielectric film 603 on the aluminum oxide film were forcibly crystallized by means of high-temperature annealing, the titanium oxide film forming the second protective film 602 would penetrate into the cracked portions formed by the high-temperature annealing and therefore the effect of reducing the leakage current would not be demonstrated unless the thickness of the planar protective film 604A were endlessly increased. When the thickness of the planar protective film 604A is increased, however, it is not possible to attain capacitance in the permitted range.

Furthermore, when the upper electrode 606 is disposed on the dielectric film 603 without the third protective film 604 and the first protective film 605 being provided, it can readily be envisaged that a short-circuiting state will be more likely to occur, as shown in FIG. 1, and the inventors have confirmed through actual experiments that defects close to short-circuiting occur. In addition, it is also difficult to maintain favorable characteristics with a structure in which only the third protective film 604 is provided between the dielectric film 603 and the upper electrode 606. When the first protective film 605 is not provided, the ultra-thin, amorphous third protective film 604 is etched relatively easily by the atmosphere (including gases such as Cl₂, HCl, H₂ and NH₃) when the upper electrode 606 is formed, and the dielectric film 603 is exposed to the atmosphere when the upper electrode 606 is formed. As a result, damage such as the oxygen deficiency 1006 and etching as shown in FIG. 1 are produced in the dielectric film 603 and the capacitor cannot readily avoid increases in leakage current.

(Method for Manufacturing a Semiconductor Device)

A method for manufacturing a semiconductor device comprising the capacitor according to this exemplary embodiment is characterized in that it makes use of a method in which, before a titanium oxide film constituting the first protective film is formed on the dielectric film, a good quality insulator (aluminum oxide or silicon dioxide) is formed as the third protective film, whereby cracks and pin holes are filled (vapor-phase infiltration afforded by means of ALD), and the defects are repaired, after which the first protective film (titanium oxide) is formed.

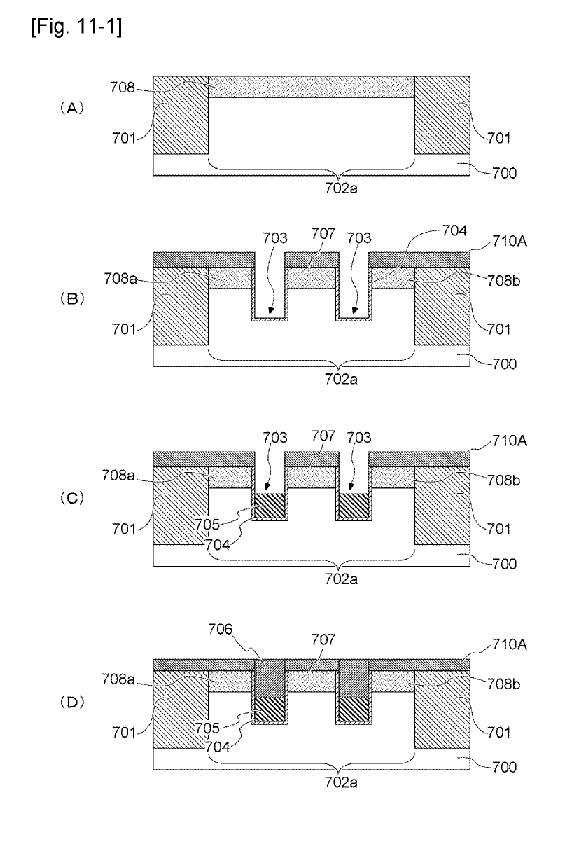

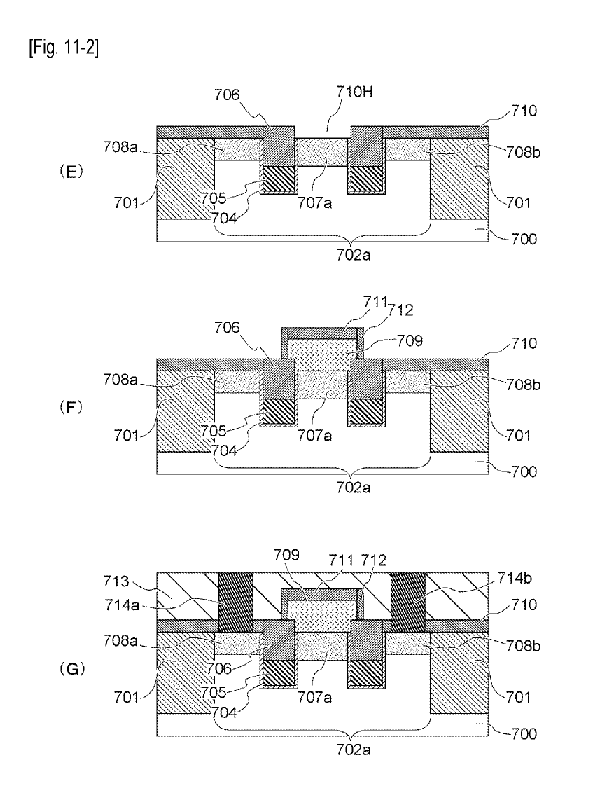

The method for manufacturing a semiconductor device comprising the capacitor according to this exemplary embodiment will be described below with reference to FIG. 11. FIG. 11(A)-11(G) (FIG. 11-1, 11-2) are process diagrams in cross section corresponding to FIG. 10.

As shown in FIG. 11(A), an active region 702a surrounded by first and second element isolation regions 730, 701 is first of all formed within a semiconductor substrate 700. Next, n-type impurity is introduced over the whole surface by means of ion implantation and an impurity diffusion layer 708 is formed on the surface of the active region 702. Next, as shown in FIG. 11(B), a mask film 710A is formed on the semiconductor substrate 700, and trenches 703 extending in the Y-direction and intersecting the active region 702 are formed. In addition, a gate insulating film 704 is formed on the inner surface thereof. By forming the trenches 703, the impurity diffusion layer 708 which is formed on the surface of the active region 702a is divided into a first capacitance diffusion layer 708a, a bit line diffusion layer 707 and a second capacitance diffusion layer 708b. Next, as shown in FIG. 11(C), a gate electrode 705 which fills the lower part of the trenches 703 and covers the gate insulating film 704 is formed. The gate electrode 705 is formed by depositing a metal film such as tungsten and then etching said metal film up to or below the bottom of the impurity diffusion layer 708. Next, as shown in FIG. 11(D), a cap insulating film 706 which fills the upper part of the trenches 703 and covers the upper surface of the gate electrode 705 is formed. Next, as shown in FIG. 11(E), a bit line contact hole 710H which opens at the upper surface of the bit line diffusion layer 707 is formed on the mask film 710A remaining on the semiconductor substrate 700. The bit line diffusion layer 707 exposed by the bit line contact hole 710H is subjected to further ion implantation in order to form a bit line diffusion layer 707a having a deeper junction than the first capacitance diffusion layer 708a and the second capacitance diffusion layer 708b. The remaining mask film 710A forms a first interlayer insulating film 710. Next, as shown in FIG. 11(F), a metal film and an insulating film are formed over the whole surface including the bit line contact hole 710H. After this, the metal film is patterned and a bit line 709 and a cover insulating film 711 extending in the X-direction are formed. Side surfaces of the bit line are then covered by a side wall insulating film 712. Next, as shown in FIG. 11(G), a second interlayer insulating film 713 is formed on the semiconductor substrate 700, after which conductive capacitance contact plugs 714 (first and second capacitance contact plugs 714a and 714b) which are connected to the first and second capacitance diffusion layers 708a, 708b formed inside the active region 702a are formed. After this, the capacitors C1, C2 etc. are formed in such a way as to be electrically connected to the upper surface of the respective capacitance contact plugs 714.

(Method for Manufacturing a Capacitor)

The lower electrode 601 (TiN) is formed by means of known CVD or ALD. For example, said lower electrode 601 may be formed in a temperature range of 350° C. to 600° C. using TiCl₄ and NH₃ as the reaction gas, for example. The lower electrode 601 is separated into individual lower electrodes 601 by forming a sacrificial interlayer film constituting a mold, then forming a cylinder hole, depositing a TiN film inside the cylinder hole, and removing the TiN film on the sacrificial interlayer film. After this, the sacrificial interlayer film is removed. It should be noted that the upper surface of the second interlayer insulating film 613 comprises a material forming a stopper film when the sacrificial interlayer film is removed.

Next, titanium dioxide (TiO₂) is formed as the second protective film 602 on the lower electrode 601. The thickness of the second protective film 602 is preferably in the range between 0.4 and 2.0 nm, and more preferably between 0.5 nm and 1.0 nm. In terms of the formation method, it is possible to use a method in which the lower electrode 601 is heat-treated under an oxidizing atmosphere such as ozone (O₃), or a known ALD method, among others.

When ALD is used in order to form the second protective film 602, TiO₂ is also formed between adjacent lower electrodes, which is to say on the second interlayer insulating film 713. TiO₂ behaves as a semiconductor, and when the TiO₂ is thickened, leakage occurs between adjacent lower electrodes so a titanium dioxide film having a certain degree of thickness is preferably formed by thermal oxidation of the surface of the lower electrode 601, after which a titanium dioxide film having a thickness of no greater than 0.20 nm is preferably formed by ALD. As a result, an ALD titanium dioxide film is continuously formed on the lower electrode 601 while a titanium dioxide film formed by means of thermal oxidation serves as a base, but a titanium dioxide film formed by means of thermal oxidation is absent from the second interlayer insulating film 713, so the structure comprising separate islands (602c) is produced.

It should be noted that when the second protective film 602 is formed only by thermal oxidation of the lower electrode 601, it goes without saying that TiO₂ is formed only on the lower electrode and therefore there is no problem in terms of leakage current between adjacent cells. However, when TiO₂ is formed by means of thermal oxidation, the electrical resistance of the lower electrode rises excessively due to the fact that oxygen diffuses along the grain boundary of TiN, and this may have an adverse effect in terms of the electrode.

Furthermore, when TiO₂ is formed by means of thermal oxidation alone, TiO₂ is not present on the second interlayer insulating film 713, and therefore a problem arises in terms of adhesion of the dielectric film 603 on the second interlayer insulating film 713 and the dielectric film 603 may peel.

In addition, the thickness of the second protective film 602 is preferably 0.4 nm or greater in order to promote growth of crystal grains and crystallization of the dielectric film 603 comprising zirconium dioxide. The second protective film 602 (TiO₂) is therefore more preferably formed by the combined use of thermal oxidation of the lower electrode 601 (TiN) and ALD. The TiO₂ which is formed by means of thermal oxidation of the lower electrode (TiN) 601 may be formed before the TiO₂ is formed by means of ALD inside the same reaction chamber, in which case the process can be simplified.

According to this exemplary embodiment, in order to form the second protective film 602, the lower electrode 601 is exposed for 30 minutes to an atmosphere comprising O₃ at 250° C. in order to oxidize the surface of the lower electrode 601 and TiO₂ of 0.4 nm is formed, after which, without further intervention, known ALD is used to additionally form a TiO₂ film corresponding to 0.1 nm inside the same reaction chamber (combined thickness: 0.5 nm).

When a film is formed by means of ALD and methylcyclopentadienyl tris(dimethylamino)titanium is used as the Ti precursor, the film formation rate per cycle of ALD film formation is approximately 0.1 nm/cycle, so 1-2 cycles are preferable. 1 cycle is used in this exemplary embodiment.

The Ti precursor is not limited to what has been described above and other Ti precursors may equally be used. In this case, the number of ALD cycles is adjusted in such a way that the target film thickness is achieved in conjunction with the ALD film formation rate.

As a result, second protective films 602a, 602b comprising titanium dioxide and each of around 0.5 nm are formed on the lower electrodes 601a, 601b, and titanium dioxide 602c corresponding to a thickness of 0.1 nm is formed on the upper surface of the second interlayer insulating film 713 which electrically isolates adjacent lower electrodes 601a, 601b.

If TiO₂ were at the level of a single molecule, then the thickness of a single-molecule layer of TiO₂ would be around 0.3 nm according to calculations, so TiO₂ at 0.1 nm does not in fact satisfy a single-molecule layer. Insulation between the adjacent lower electrodes 601a, 601b can therefore be maintained while improving adhesion by interposing the island-like second protective films 602c between the second interlayer insulating film 713 present between the adjacent lower electrodes 601a, 601b and the dielectric film 603 formed thereon. Although the film is not actually continuous in this exemplary embodiment, for the sake of convenience it is still treated as a “film” or “layer” when it is present in such a form.

A dielectric film 603 comprising zirconium dioxide (ZrO₂) as the main component is then formed on the second protective film 602. A known ALD method such as that described in Patent Document 3 may be used as the film formation method. In this exemplary embodiment, cyclopentadienyl tris(dimethylamino)zirconium is used as the Zr precursor and the process is carried out at a processing temperature of 250° C. A processing temperature of between 220° C. and 280° C. may be used. A gas comprising O₃ may be used as the oxidizing reaction gas, for example.

The thickness of the dielectric film 603 is preferably set at 5.0 nm or greater, including the thickness of the third protective film which will be described later, and more preferably it is set at 5.5 nm or greater. In this exemplary embodiment, the thickness of the dielectric film 603 is 5.0 nm and the third protective film 604 (aluminum oxide) is obtained by three cycles of ALD employing trimethylaluminum (TMA) (corresponding to 0.3 nm), giving a combined thickness of 5.3 nm.

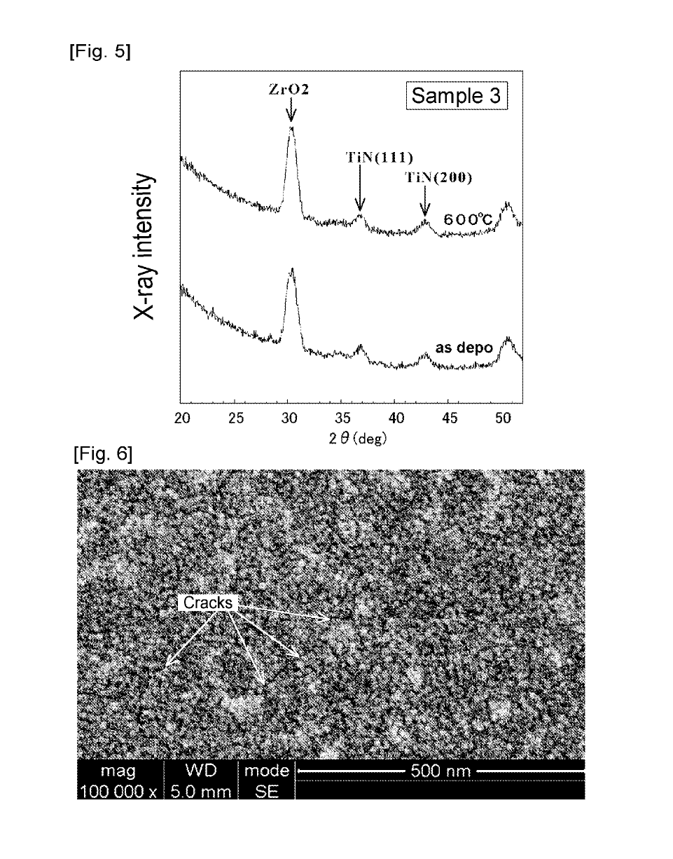

As shown in FIGS. 3 and 4 described above, if the thickness of the dielectric film 603 is 4 nm or less, the zirconium dioxide is amorphous or microcrystalline such that a peak is not displayed in XRD, but crystallization and crystal grain growth progress beyond 4 nm and up to 5 nm so a clear peak can be seen in XRD. Volume shrinkage of the dielectric film 603 occurs as this takes place and as shown in FIG. 8, defects 610 such as cracks and pin holes which develop in the thickness direction from the upper surface 603S are formed.

Furthermore, the dielectric film 603 may be doped using Al or Si as impurity in order to increase the thermal stability and to adjust the degree of crystallization. In this exemplary embodiment, the Al-doped layer 603B is introduced at four equally divided locations in the film thickness direction of the dielectric film 603 using the ASB-ALD method described in Patent Document 5, as shown in FIG. 8.

The impurity concentration may be controlled by the number of times of doping employing ASB-ALD which is carried out while the dielectric film 603 is being formed. In this exemplary embodiment, for example, Al-doping is introduced at equal intervals in the thickness direction of the dielectric film 603 four times with respect to the thickness of the zirconium dioxide film 603A using ASB-ALD. In this process, the concentration of Al expressed as Al/(Al+Zr) taken in terms of the whole of the dielectric film 603 is approximately 2%.

On the other hand, as will be described later, the doping need not necessarily be introduced at equal intervals in the film thickness direction and the concentration may be varied in the thickness direction by varying the intervals in the thickness direction.

According to investigations carried out by the present inventors, crystal growth is less likely to progress with a higher impurity concentration, taken as an average of the impurity contained in the dielectric film 603, and if other conditions are the same, the film thickness at which crystal grains start to grow tends to shift to the thicker side. Furthermore, the XRD peak intensity immediately after film formation tends to be smaller when the impurity concentration is higher, even in the case of zirconium dioxide films having the same film thickness beyond 5 nm.

For example, the results of a comparison when the concentration of Al expressed as Al/(Al+Zr) was 3%, 4% and 6% with respect to a ZrO₂ film having a thickness of 7 nm show that immediately after film formation (“as depo.”), the XRD diffraction peak is clearly smaller when the impurity concentration is higher and it can be understood that the mean particle size of the crystal grains is affected by the impurity concentration.

Furthermore, virtually the same XRD diffraction peak is exhibited at any level after annealing for 6 hours under N₂ at 450° C. for the three impurity concentrations mentioned above, and it can be understood that the mean particle size of the crystal grains is substantially uniform. That is to say, it is possible to control the crystallinity of the dielectric film 603 immediately after film formation and control the level of crack/pin hole formation in accordance with the profile and doping concentration of impurity in the dielectric film 603.

The dielectric film 603 is in an amorphous state immediately after film formation and a state in which formation of cracks/pin holes is restricted is produced as a result of the impurity concentration being increased, and a method in which annealing is carried out at a relatively high temperature (e.g. a temperature above 450° C.) could be considered in order to promote crystallization after the first protective film 605 and the upper electrode 606 have been formed, but when this kind of method is actually implemented not only does the dielectric constant failed to increase in the same way as in Patent Document 1, but defects 610 such as cracks are also formed in the dielectric film 603 at that point in time (at the point in time when crystallization is promoted). The surfaces of the cracks 610 which are produced form dangling bonds that form a trap level, and a leak path is formed at the high working temperature of the device (90-110° C.).

The dielectric film 603 is therefore preferably densified to the extent possible before the third protective film 604 is formed and steps are taken to ensure that a thermal load is not applied as far as possible in the subsequent manufacturing steps. To be specific, steps are preferably taken to ensure that the temperature does not exceed 450° C., more preferably to ensure that the temperature does not exceed 420° C., and even more preferably to ensure that the temperature does not exceed 400° C.

Furthermore, when impurity doping is performed using normal ALD or co-adsorption ALD employing a Zr precursor and an Al precursor, as described in Patent Document 5, the surface density of Al adhering in one cycle of ALD employed in Al-doping is excessively high and ZrO₂ crystal growth no longer reaches beyond the impurity-doped region. As a result, the dielectric film 603 does not readily crystallize and there is also a reduction in dielectric constant.

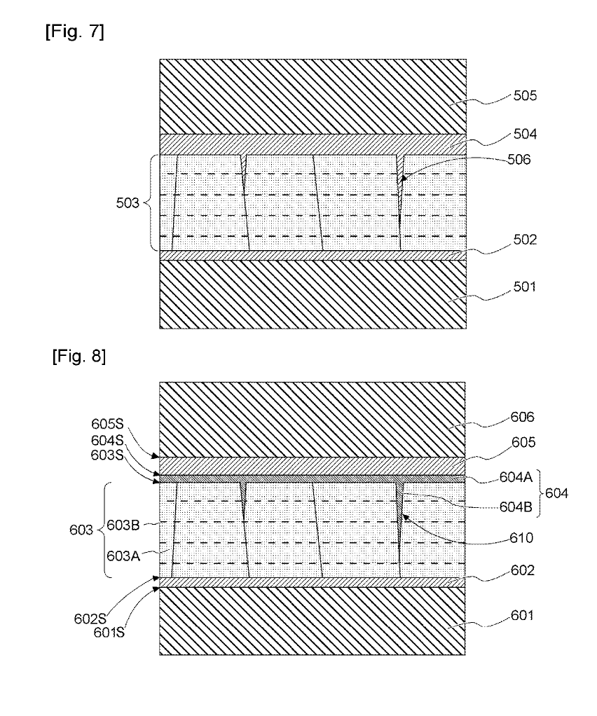

However, when doping is carried out using the ASB-ALD method described in Patent Document 5, the surface density of Al adhering in one cycle of ALD employed in Al-doping can be reduced in comparison with a conventional ALD method and this kind of impurity-doped region (doped layer) produces a state in which crystallization of ZrO₂ is not inhibited, and crystallization and growth of crystal grains are promoted to the extent that a diffraction peak can already be confirmed by XRD immediately after a film has been formed to around 5 nm (see FIG. 5).

If the dielectric film 603 is not sufficiently crystallized after film formation because of the impurity concentration or film formation conditions, heat treatment employing an oxidizing atmosphere may be carried out in order to cause crystallization and growth of crystal grains. This makes it possible to improve the crystallinity of the dielectric film 603 and to densify the dielectric film 603, and cracks may be intentionally formed in a controlled state.

Furthermore, even if the dielectric film 603 crystallizes, heat treatment employing an oxidizing atmosphere may still be performed, as required, with the aim of restoring residual oxygen deficiency in the dielectric film 603 and with the aim of further improving the crystallinity. The heat treatment in an oxidizing atmosphere may be carried out at a temperature of between 250° C. and 450° C., but a temperature of between 350° C. and 420° C. is more preferable. In particular, when O₃ is used as an oxidant, the heat treatment is preferably carried out at between 350° C. and 400° C. in order to prevent abnormal oxidation of the dielectric film 603 and of the lower electrodes 601 via the cracks/pin holes present in the dielectric film.

However, annealing in an inert atmosphere such as N₂, Ar or He or in an atmosphere comprising a reducing gas such as H₂ in particular induces oxygen deficiency in the dielectric film 603 and is therefore undesirable. Oxygen deficiency in the dielectric film 603 forms a trap level, which causes an increase in the leakage current. In addition, heat treatment over a long period of time at a temperature above 500° C. is also undesirable because mutual diffusion starts at the interface of each layer.

Aluminum oxide is then deposited by means of known ALD as the third protective film 604 on the crystallized dielectric film 603. The third protective film 604 is formed using conventional ALD, and ASB-ALD is not employed.

This process is intended to correct defects by filling cracks or pin holes formed in the dielectric film 603 using a high-quality insulating film, and to prevent penetration of the titanium dioxide first protective film 605 (to be described later) into the cracks or pin holes.

The third protective film 604 is preferably thicker from the point of view of filling the cracks or pin holes, but Al₂O₃ has a dielectric constant of 9.0 and SiO₂ has a dielectric constant of 3.9, for example, which are far smaller than the dielectric constant of ZrO₂ at 32-38, so increasing the thickness of the film makes it difficult to obtain a small EOT. The film thickness cannot therefore be excessively increased.

When the third protective film 604 is formed by aluminum oxide, the film formation may be carried out using TMA and O₃ at a temperature in the range of 220° C. to 400° C., for example. The film formation rate in this case is 0.09 nm per ALD cycle.

Investigations carried out by the present inventors showed that when a film is formed using ALD employing TMA and O₃, an adequate effect is demonstrated if 2-5 cycles are carried out, in accordance with the required correction level. This corresponds to 0.18 nm-0.45 nm as the film thickness formed on the upper surface 603S of the dielectric film 603.

Assuming that Al₂O₃ is at the level of a single molecule, the thickness of a single-molecule layer is approximately 0.35 nm according to calculations, so an approximately single-molecule layer is produced by four cycles.

According to this exemplary embodiment, a film is formed for three cycles (corresponding to 0.27 nm) at 250° C. using TMA and O₃ as a reaction gas and employing normal ALD. As a result, the third protective film 604 is formed, comprising the planar protective film 604A which is formed on the surface of the dielectric film 603 and the defect-filling film 604B which is in contact with the planar protective film 604A and projects from the planar protective film 604A in such a way as to fill the cracks 610.

The cracks and pin holes are filled by the third protective film 604 as a result of vapor-phase infiltration, as has already been described, so the time (dosing time) taken for the step of supplying TMA to the ALD reaction chamber in accordance with the ALD sequence is preferably set to be several times longer (e.g. between two times and 10 times longer) than in the case of normal ALD film formation. Specifically, a time of the order of 60 seconds-600 seconds is selected, for example.

Furthermore, the oxidation step employing O₃ is also preferably set to be longer than that of the normal ALD sequence in the same way as for the step of supplying TMA in order to fill the deep parts of the cracks or pin holes. It is vital that the oxidation step etc. be suitably modified in order to restrict formation of a new leak path by carbon impurity etc. Specifically, a time of the order of 60 seconds-600 seconds is selected in the same way as for TMA. According to this exemplary embodiment, a dosing time of 120 seconds is used for TMA and a dosing time of 120 seconds is used for O₃. The correction of defects by means of vapor-phase infiltration must be carried out after the dielectric film 603 has been formed and before the first protective film 605 is formed, as indicated above. Furthermore, the same also applies when another insulator is used as the third protective film (defect-filling film 604A).

After the correction level has been reached, it is possible to return to the dosing time for normal ALD film formation to form the planar protective film 604A. Furthermore, if a precursor in the film formation space is also oxidized without the source gas being purged, CVD conditions are produced and it is possible to increase the film formation rate in one cycle. That is to say, the defect-filling film 604B and the planar protective film 604A may comprise insulators comprising the same material formed in separate processes.

Investigations carried out by the present inventors show that gas-phase infiltration of the aluminum oxide does not demonstrate an adequate effect with CVD, and ALD must be carried out at least until the correction level is reached.

When the third protective film 604 and the dielectric film 603 are formed at the same temperature, the film formation may take place continuously inside the same reaction chamber so that the process can be simplified. Furthermore, if the temperature at which the third protective film 604 is formed is selected to be greater than the temperature at which the dielectric film 603 is formed, the dielectric film 603 may be exposed to an oxidizing atmosphere before the third protective film 604 is formed, and as a result this can also serve as the heat treatment under an oxidizing atmosphere which is carried out as required after the dielectric film 603 has been formed, and which also makes it possible simplify the process.

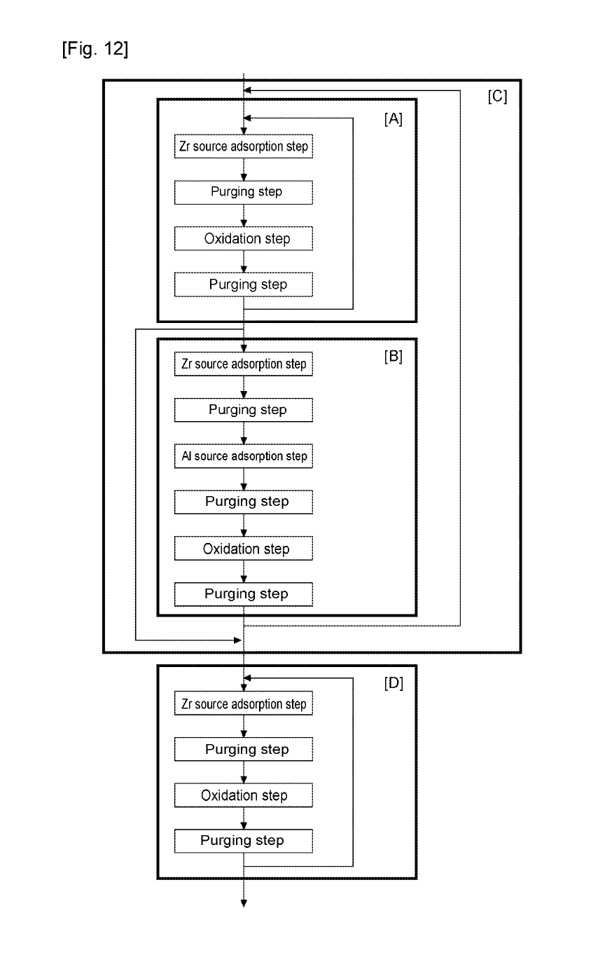

FIG. 12 shows an ALD flowchart in a case in which the dielectric film 603 and the third protective film 604 are continuously formed. First of all, step [A] is a step in which the zirconium dioxide film 603A is formed, where Zr source adsorption/purging/oxidation/purging constituting one cycle are repeated until a predetermined film thickness is reached. Next, step [B] is a step in which the Al-doped layer 603B is formed by means of ASB-ALD, where Zr source adsorption/purging/Al source adsorption/purging/oxidation/purging constitute one cycle. In addition, the dielectric film 603 is formed by means of step [C] in which step [A] and step [B] are repeated the required number of times. The final step of step [C] involves performing step [A] without step [B]. Following on from this, step [D] is an ALD step for forming the third protective film 604, where Al source adsorption/purging/oxidation/purging constituting one cycle are repeated the required number of times. The Zr source (Zr precursor) in step [B] has a bulky group which can restrict the adsorption site of the Al source (Al precursor), and the abovementioned cyclopentadienyl tris(dimethylamino)zirconium or the like may be suitably used. There is no particular limitation as to the Zr source (Zr precursor) in step [A], and a known Zr precursor may be used.

The first protective film 605 comprising TiO₂ is formed on the third protective film 604 next. The first protective film 605 serves to restrict damage imparted to the dielectric film 603 and the third protective film 604 when the upper electrode 606 is formed. The first protective film 605 may be formed by means of known ALD. The film thickness is preferably between 0.4 nm and 3.0 nm, and more preferably between 0.6 nm and 2.0 nm. In this exemplary embodiment, ALD is used to form the first protective film 605, methylcyclopentadienyl tris(dimethylamino)titanium is used as the Ti precursor, O₃ is used as the oxidant, and six cycles of ALD film formation are carried out to produce a film thickness of approximately 0.6 nm.

TiN constituting the upper electrode 606 is formed next using known ALD or CVD employing TiCl₄ and NH₃ gas. The film thickness is preferably 4 nm-10 nm. The film formation temperature is preferably between 350° C. and 450° C. If the temperature exceeds 450° C., new cracks may be formed in the dielectric film 603 etc., and the surfaces of the cracks produced may form dangling bonds that form a trap level, and a minute leak path may be formed in the high-temperature working environment of the device. Furthermore, if the temperature is lower than 350° C., the concentration of residual chlorine in the TiN film may increase, which may cause a problem in terms of adhesion. After the upper electrode has been formed, the thermal load applied to the capacitor is set at no greater than 450° C., preferably no greater than 420° C., and more preferably no greater than 400° C. In this exemplary embodiment, the upper electrode 606 is formed using ALD at a temperature of 400° C. to produce a film thickness of 7 nm.

After this, a B—SiGe-Poly film is formed to a thickness of 100 nm as the trench-filling upper electrode 607 using diborane, silane and germane as a reaction gas, and tungsten (W) is further formed by means of sputtering as the plate electrode 608. After this, the plate electrode 608 and the trench-filling upper electrode 607 formed in regions other than a memory cell region are removed using a known lithography technique and a known dry etching technique. The EOT of the capacitor formed in this way is 0.74 nm, and the leakage current is approximately 8 fA/cell (8 E-15 A/cell) at 90° C. with an applied voltage of ±1 V.

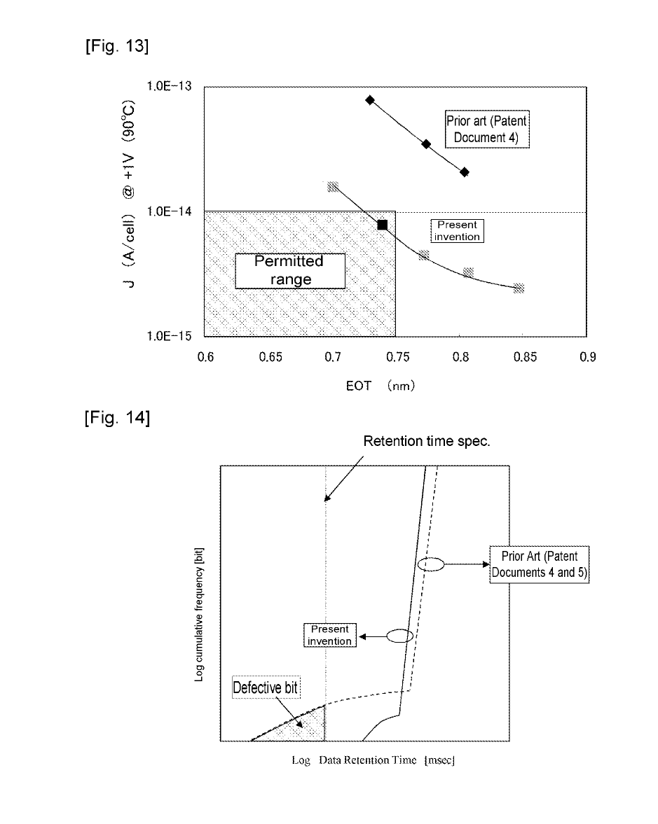

FIG. 13 shows the results of a comparative evaluation of the relationship between leakage current density J (A/cell) and equivalent oxide thickness EOT (nm) for the capacitor having a TZAZT structure described in Patent Document 4 (prior art) and a capacitor having a TAZT structure according to this exemplary embodiment (present invention). A TZAZT structure and TAZT structure cannot be manufactured at the same time on the same semiconductor substrate, so the combined evaluation results are shown for capacitors formed on separate semiconductor substrates. It is difficult to directly measure the EOT depicted on the horizontal axis from a capacitor having a three-dimensional structure, so the EOT value is calculated from the capacitance value of a flat capacitor produced at the same time as the three-dimensional structure for which the area is known. For the leakage current density J depicted on the vertical axis, a single parallel capacitor in which 1 million crown-structure capacitors shown in FIG. 10 are connected in parallel is produced, after which the leakage current/applied voltage characteristics are measured, and the result is converted to leakage current per capacitor, based on the leakage current value at an applied voltage of +1 V. The leakage current is measured at a high temperature of 90° C.

As is clear from FIG. 13, in the case of the conventional TZAZT structure under a high temperature of 90° C., it is not possible to achieve results that satisfy the permitted range, namely an EOT of no greater than 0.75 nm and a leakage current density of no greater than 1 E-14 (A/cell). On the other hand, with the TAZT structure of this exemplary embodiment, it is possible to achieve results that satisfy the permitted range under a high temperature of 90° C., the EOT being 0.74 nm and the leakage current density being 8 E-15 (A/cell).

Furthermore, FIG. 14 shows a comparison of the cumulative frequency distribution of the data retention time when the 2 Gbit DRAM shown in FIG. 9 and FIG. 10 is produced in accordance with the prior art and in accordance with the present invention in the same way as described above. Evaluation results are taken under a high temperature of 90° C. in both cases. As shown in FIG. 14, defective bits which do not satisfy the specification for data retention time (holding time) are present in the prior art, showing that the article is unsuitable as a DRAM semiconductor device. On the other hand, when the present invention is employed, it is possible to reduce the number of minority defect bits which do not satisfy the specification for data retention time to zero, showing that the article has good characteristics as a DRAM semiconductor device.

### Second Exemplary Embodiment

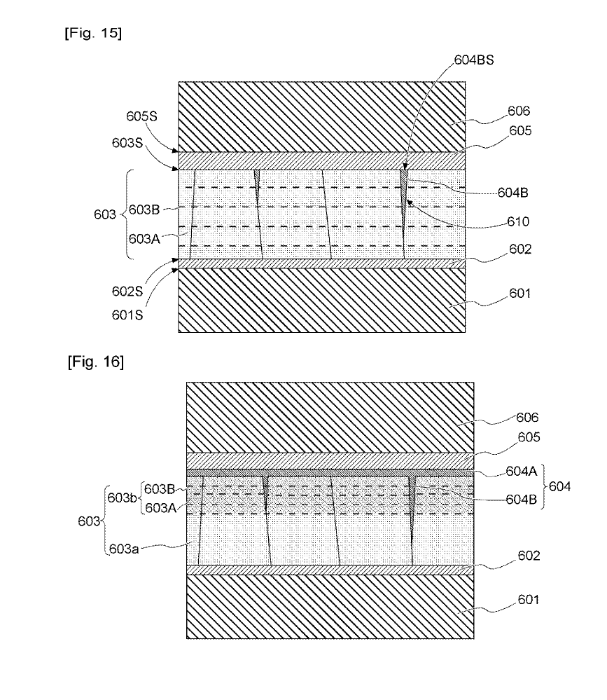

In the first exemplary embodiment, the third protective film 604 comprises the planar protective film 604A and the defect-filling film 604B, as shown in FIG. 8. In a capacitor according to the second exemplary embodiment, as shown in FIG. 15, the planar protective film 604A which covers the upper surface 603S of the dielectric film 603 is absent, and only the defect-filling film 604B which fills the cracks (defects) 610 is present. The first protective film 605 is in contact with the upper surface 603S of the dielectric film 603 and with an upper surface 604BS of the defect-filling film 604B. It should be noted that the upper surface 604BS of the defect filling film 604B is shown flush with the upper surface 603S of the dielectric film 603, but this is not limiting and the upper surface 604BS may equally be slightly set back from the upper surface 603S.

The semiconductor device according to this exemplary embodiment therefore comprises a capacitor provided with: the lower electrode 601 which is disposed on the semiconductor substrate; the second protective film 602 which is at least in contact with the lower electrode 601 and covers the upper surface 601S; the dielectric film 603 which is in contact with the second protective film 602, covers the upper surface 602S thereof and has cracks (defects) 610 extending in the film thickness direction; the third protective film 604 which includes at least the defect-filling film 604B comprising an insulating film which fills the defects 610; the first protective film 605 which covers the dielectric film 603 and the third protective film 604; and the upper electrode 606 which is in contact with the first protective film 605 and covers the upper surface 605S thereof.

According to this exemplary embodiment, the first protective film 605 is provided in a state in which the defects are filled by the defect-filling film 604B. The first protective film 605 is therefore not formed inside the defects 610, and it is possible to restrict an increase in the leakage current under a high temperature in the same way as in the first exemplary embodiment. In addition, the planar protective film 604A which forms part of the third protective film 604 is not present on the upper surface 603S of the dielectric film 603 so it is possible to increase the capacitance of the capacitor by reducing the EOT by around 0.2 nm.

When aluminum oxide is used for the third protective film in the configuration described above, for example, said aluminum oxide is in an amorphous state immediately after formation by means of ALD and it can be more easily removed by etching using chlorine-containing gas plasma than crystalline aluminum oxide. That is to say, the thickness of the planar protective film 604A formed on the upper surface of the dielectric film 603 is less than the thickness of the defect-filling film 604B, which fills the defects, in the thickness direction of the dielectric film 603, so the planar protective film 604A alone can be selectively removed. Furthermore, when silicon dioxide or silicon nitride is used as the third protective film, etching can be easily carried out in a SF₆ or HF atmosphere.

### Third Exemplary Embodiment

The first and second exemplary embodiments employ a configuration for the dielectric film 603 in which impurity-doped layers are provided at equal intervals in the thickness direction of the dielectric film 603 using ASB-ALD. In the third exemplary embodiment, as shown in FIG. 16, impurity-doped layers 603B formed by ASB-ALD are not disposed at equal intervals in the film thickness direction, rather they are unevenly distributed within the dielectric film 603. That is to say, the dielectric film 603 comprises: a first dielectric film 603a which does not contain impurity and is in contact with the upper surface of the second protective film 602 disposed on the upper surface of the lower electrode 601; and the second dielectric film 603b which contains impurity and is in contact with the upper surface of the first dielectric film 603a. Furthermore, the impurity-doped layers 603B are arranged equally in the thickness direction within the zirconium dioxide film 603A in the second dielectric film 603b. Defects in the dielectric film 603 are filled by the defect-filling film 604B and the planar protective film 604A is disposed on the upper surface of the second dielectric film 603b. The first protective film 605 is disposed on the upper surface of the planar protective film 604A, and the upper electrode 606 is further disposed on the upper surface thereof.

In this exemplary embodiment also, the impurity-doped layers 603B are formed by means of ASB-ALD and crystallization of the dielectric film proceeds over the whole of the thickness direction. It is therefore possible to restrict an increase in the leakage current under a high temperature by filling the defects 610 using the defect-filling film 604B while increasing the dielectric constant of the dielectric film 603 in the same way as in the first and second exemplary embodiments. It should be noted that in this exemplary embodiment, the second dielectric film 603b is disposed on the upper electrode 606 side, but this is not limiting and it may equally be disposed on the lower electrode 601 side. Furthermore, it may be offset towards the central portion. The planar protective film 604A may be removed in the same way as in FIG. 15 relating to the second exemplary embodiment.

### Fourth Exemplary Embodiment

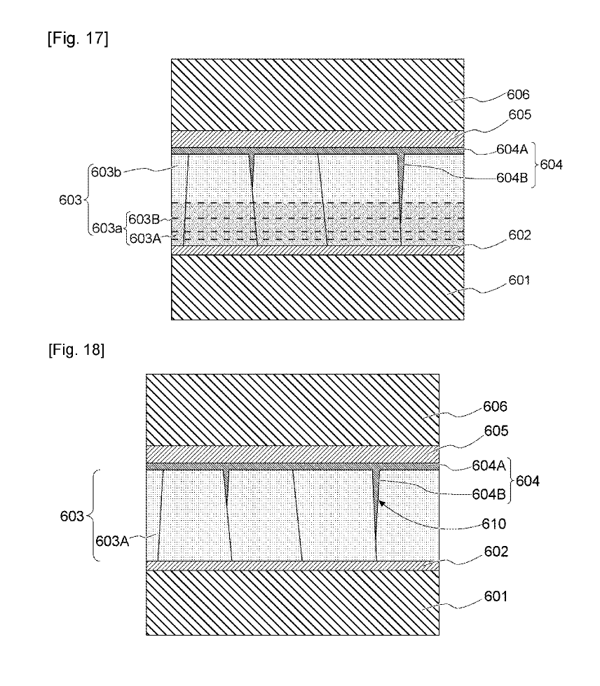

In the third exemplary embodiment, the second dielectric film 603b comprising the impurity-doped layers 603B formed by ASB-ALD are unevenly distributed in the dielectric film 603, and the impurity-doped layers 603B within the second dielectric film 603b are disposed at equal intervals in the thickness direction within the second dielectric film 603b. In the fourth exemplary embodiment, as shown in FIG. 17, the impurity-doped layers 603B within the uneven dielectric film which contains the impurity-doped layers 603B are not evenly distributed, rather they are unevenly distributed in the thickness direction. That is to say, the capacitor according to this exemplary embodiment comprises: the first dielectric film 603a which is in contact with the upper surface of the second protective film 602 disposed on the upper surface of the lower electrode 601 and contains the impurity-doped layers 603B; and the second dielectric film 603b which is in contact with the upper surface of the first dielectric film 603a and does not contain impurity, and the impurity-doped layers 603B contained in the first dielectric film 603a are not evenly distributed in the thickness direction within the first dielectric film 603a, rather they are arranged at different intervals in the thickness direction. The other constituent elements are the same as in the abovementioned exemplary embodiments. The planar protective film 604A may equally be removed from the configuration of this exemplary embodiment, in the same way as in FIG. 15 relating to the second exemplary embodiment.

### Fifth Exemplary Embodiment

In the first to fourth exemplary embodiments, at least the impurity-doped layers 603B formed by ASB-ALD are contained in the dielectric film 603. In this exemplary embodiment, as shown in FIG. 18, the dielectric film 603 does not contain impurity-doped layers. That is to say, in the fifth exemplary embodiment, the defect-filling film 604B which fills the defects 610 produced in the dielectric film 603 comprising a single layer, namely the zirconium dioxide film 603A, is formed, and as a result the planar protective film 604A comprising the same material is also formed on the dielectric film 603. As described above, the planar protective film 604A is formed by normal ALD and is present as a continuous film. The planar protective film 604A can therefore function in the role of the impurity-doped layers 603B provided in the dielectric film 603, from the point of view of suppressing an increase in leakage current. In this case, an aluminum oxide film is preferred as the planar protective film 604A, and if a silicon dioxide film or a silicon nitride film is formed as the defect-filling film 604B, it is possible to remove the film on the surface of the dielectric film, as described in the second exemplary embodiment, and then to form a separate aluminum oxide film as the planar protective film 604A. The planar protective film 604A and the defect-filling film 604B can thus be formed from separate materials. For example, if a silicon dioxide film is formed as the defect-filling film 604B, said film may be formed to a thickness of 0.1 nm or more by means of ALD employing ozone (O₃) and tris(dimethylamino)silane (SiH(Me₂N)₃) or dichlorosilane (SiH₂Cl₂) as a reaction gas, at a processing temperature of 300° C.-400° C. (350° C.-400° C. in the case of dichlorosilane), after which the silicon dioxide film on the surface of the dielectric film 603 may be removed in a SF₆ or HF atmosphere, and then the aluminum oxide planar protective film 604A may be formed in a range of 0.1-1.0 nm by means of ALD. The abovementioned Si precursor may be a silicon nitride film modified by a nitriding gas such as ammonia (NH₃). The defects 610 in the dielectric film 603 are filled by the defect-filling film 604B so the first protective film 605 is not formed within the defects 610, in the same way as in the exemplary embodiments described above. As a result, it is possible to suppress an increase in leakage current under a high temperature, and the leakage current in the dielectric film 603 as a whole in the portions without defects can be prevented from increasing by the planar protective film 604A.

Furthermore, the description above relates to a case in which titanium nitride (TiN) is used for the upper and lower electrodes of the capacitor, but this is not limiting and other metallic materials which can form an MIM capacitance which is useful for a high-capacitance capacitor may be employed, in particular materials exhibiting a greater work function, for example those which have a higher work function than 5.1 eV such as Pt, Ru and RuO₂, for example, may be used. TiN which can be formed by CVD that has excellent properties of covering differences in level is preferably used for the cylindrical (crown-type) lower electrode illustrated in the exemplary embodiments.

### KEY TO SYMBOLS

601, 601a, b . . . Lower electrode
601S . . . Lower electrode upper surface
602, 602a-c . . . Second protective film
602S . . . Second protective film upper surface
603 . . . Dielectric film
603A . . . Zirconium oxide film
603B . . . Impurity (Al)-doped layer
603a . . . First dielectric film
603b . . . Second dielectric film
603S . . . Dielectric film upper surface
604 . . . Third protective film
604A . . . Planar protective film
604B . . . Defect-filling film
604S . . . Third protective film upper surface
604BS . . . Defect-filling film upper surface
605 . . . First protective film
605S . . . First protective film upper surface
606 . . . Upper electrode
607 . . . Trench-filling upper electrode
608 . . . Plate electrode
700 . . . Semiconductor substrate
701 . . . Second element isolation region
702, 702a, b . . . Active region
703 . . . Trench
704 . . . Gate insulating film
705 . . . Gate electrode
706 . . . Cap insulating film
707, 707a . . . Bit line diffusion layer
708 . . . Impurity diffusion layer
708a . . . First capacitance diffusion layer
708b . . . Second capacitance diffusion layer
709 . . . Bit line
710 . . . First interlayer insulating film
710a . . . Mask film
710H . . . Bit line contact hole
711 . . . Cover insulating film
712 . . . Side wall insulating film
713 . . . Second interlayer insulating film
714 . . . Capacitance contact plug
714a . . . First capacitance contact plug
714b . . . Second capacitance contact plug
730 . . . First element isolation region

1. A semiconductor device comprising a capacitor, the capacitor comprising:
a lower electrode disposed on a semiconductor substrate;
a second protective film which covers at least the surface of the lower electrode;
a dielectric film which covers the surface of the second protective film and has a defect which develops in the film thickness direction from an upper surface opposite the second protective film;
a third protective film having at least a defect-filling film comprising an insulator which fills the defect and is different from the main component of the dielectric film;
a first protective film which covers the dielectric film and the third protective film; and
an upper electrode which covers the first protective film.

2. The semiconductor device as claimed in claim 1, wherein the third protective film comprises the defect-filling film and a planar protective film which covers the upper surface of the dielectric film.

3. The semiconductor device as claimed in claim 2, wherein the defect-filling film and the planar protective film are made of the same material.

4. The semiconductor device as claimed in claim 1, wherein the defect-filling film is an insulator selected from any of an aluminum oxide, silicon dioxide and silicon nitride.

5. The semiconductor device as claimed in claim 1, wherein the first and second protective films comprise titanium oxide as the main component.

6. The semiconductor device as claimed in claim 5, wherein the first protective film has a thickness in the range of 0.4-3.0 nm, and the second protective film has a thickness in the range of 0.4-2.0 nm.

7. The semiconductor device as claimed in claim 1, wherein the dielectric film comprises zirconium oxide as the main component.

8. The semiconductor device as claimed in claim 7, wherein the dielectric film comprising zirconium oxide as the main component is such that M is 2% or less, expressed as M/(Z+M) where Z is the number of zirconium atoms and M is the number of impurity atoms.

9. The semiconductor device as claimed in claim 8, wherein the impurity is present in the zirconium oxide in at least one impurity-doped layer which is doped at a surface density of less than 1.4 E+14 (atoms/cm²).

10. The semiconductor device as claimed in claim 9, wherein the dielectric film has a structure in which a second dielectric film comprising zirconium oxide to which impurity has been added in the planar direction is stacked on a first dielectric film of 4 nm or less which is in contact with the second protective film and comprises a zirconium oxide film to which impurity is not added, the total thickness of the first dielectric film, the second dielectric film and the third protective film being between 5 nm and 7 nm.

11. The semiconductor device as claimed in claim 9, wherein the dielectric film has a structure in which a second dielectric film of 4 nm or less comprising zirconium oxide to which impurity is not added is stacked on a first dielectric film which is in contact with the second protective film and comprises a zirconium oxide film to which impurity has been added in multiple layers at unequal intervals in the planar direction, the total thickness of the first dielectric film, the second dielectric film and the third protective film being between 5 nm and 7 nm.

12. The semiconductor device as claimed in claim 10, wherein the defect penetrates the second dielectric film and develops up to at least part of the first dielectric film.

13. The semiconductor device as claimed in claim 1, wherein the capacitor is such that the combined equivalent oxide thickness EOT of the dielectric film and the third protective film is no greater than 0.75 nm and the leakage current density at 90° C. is no greater than 1 E-14 (A/cell).

14. A semiconductor device having a capacitor, the capacitor comprising:
a lower electrode comprising titanium nitride as the main component provided in such a way as to be connected to a semiconductor substrate;
a second protective film comprising titanium oxide as the main component provided in contact with the lower electrode;
a dielectric film which is provided in contact with the second protective film, comprises crystallized zirconium oxide as the main component, and has a defect which develops in the film thickness direction from an upper surface opposite the second protective film;
a third protective film which has a defect-filling film which fills the defect in the dielectric film and comprises a non-crystallized insulator;
a first protective film which comprises titanium oxide as the main component, covers the dielectric film and is provided in contact with the third protective film; and
an upper electrode comprising titanium nitride as the main component provided in contact with the first protective film.

15. The semiconductor device as claimed in claim 14, wherein the defect-filling film is an insulator selected from any of aluminum oxide, silicon dioxide and silicon nitride.

16. The semiconductor device as claimed in claim 14, wherein the dielectric film includes at least one impurity-doped layer including an impurity metal different from zirconium in the planar direction.

17. The semiconductor device as claimed in claim 16, wherein the dielectric film comprises a first dielectric film that does not include the impurity-doped layer, and a second dielectric film that includes the impurity-doped layer.

18. The semiconductor device as claimed in claim 14, wherein the third protective film includes a planar protective film comprising aluminum oxide having a thickness in the range of 0.1 nm to 1.0 nm between the dielectric film and the first protective film.

19. The semiconductor device as claimed in claim 14, wherein the first protective film has a thickness in the range of 0.4-3.0 nm and the second protective film has a thickness in the range of 0.4-2.0 nm.

20. The semiconductor device as claimed in claim 14, wherein the total thickness of the dielectric film and the third protective film is between 5.0 nm and 7.0 nm.

21. A method for manufacturing a semiconductor device comprising a capacitor, the method comprising:
forming a lower electrode comprising titanium nitride as the main component on a semiconductor substrate;
forming a second protective film comprising titanium oxide as the main component on the lower electrode;
forming a dielectric film comprising crystallized zirconium oxide as the main component on the second protective film;
subjecting an insulator to vapor-phase infiltration as a third protective film on the dielectric film;
forming a first protective film comprising titanium oxide as the main component following the step in which vapor-phase infiltration is performed; and
forming an upper electrode comprising titanium nitride as the main component on the first protective film.

22. The method for manufacturing a semiconductor device as claimed in claim 21, wherein subjecting an insulator to vapor-phase infiltration as the third protective film on the dielectric film further comprises:
forming a defect-filling film comprising the insulator which fills a defect developed in the film thickness direction from an upper surface of the dielectric film; and
depositing a planar protective film comprising the insulator on the upper surface of the dielectric film.

23. The method for manufacturing a semiconductor device as claimed in claim 22, comprising, before the first protective film is formed, removing the planar protective film on the surface of the dielectric film.

24. The method for manufacturing a semiconductor device as claimed in claim 21, wherein forming the second protective film comprising titanium oxide as the main component comprises at least oxidizing the surface of the lower electrode comprising titanium nitride as the main component, and forming titanium oxide by means of ALD.

25. The method for manufacturing a semiconductor device as claimed in claim 21, wherein forming the dielectric film comprising zirconium oxide as the main component comprises forming at least one impurity-doped layer which is doped at a surface density of less than 1.4 E+14 (atoms/cm²) in the zirconium oxide film.

26. The method for manufacturing a semiconductor device as claimed in claim 25, wherein the impurity-doped layer is formed by multiple layers in which the concentration of M is in the range of 2% or less, expressed as M/(Z+M) where Z is the number of zirconium atoms and M is the number of impurity metal atoms in the dielectric film.

27. The method for manufacturing a semiconductor device as claimed in claim 26, wherein the impurity-doped layer is formed by means of an ALD cycle comprising:
absorbing a first source gas comprising cyclopentadienyl tris(dimethylamino)zirconium or methylcyclopentadienyl tris(dimethylamino)zirconium is supplied as a zirconium precursor and said zirconium precursor;
purging the first source gas;
absorbing a second source gas including a precursor that includes the impurity metal atoms is supplied and the precursor including the impurity metal atoms at an adsorption site restricted by the zirconium precursor;
purging the second source gas; and
oxidizing the adsorbed zirconium precursor and precursor including the impurity metal atoms.

28. The method for manufacturing a semiconductor device as claimed in claim 25, wherein forming the dielectric film comprising zirconium oxide as the main component comprises stacking a first dielectric film of 4 nm or less to which impurity is not added and a second dielectric film to which impurity has been added in succession, the total thickness of the first dielectric film, the second dielectric film and the third protective film being between 5 nm and 7 nm.

29. The method for manufacturing a semiconductor device as claimed in claim 21, further comprising, after the dielectric film has been formed and before the third protective film is formed, subjecting the dielectric film to heat treatment at a temperature selected from the range between 220° C. and 450° C. under an oxidizing atmosphere.

30. The method for manufacturing a semiconductor device as claimed in claim 21, wherein subjecting an insulator to vapor-phase infiltration as a third protective film on the dielectric film is carried out by means of atomic layer deposition (ALD).

31. The method for manufacturing a semiconductor device as claimed in claim 30, wherein the vapor-phase infiltration which is carried out by the abovementioned ALD involves a reaction gas dosing time of 60 seconds-600 seconds at least while the defect-filling film is formed.

32. The method for manufacturing a semiconductor device as claimed in claim 30, wherein the main component of the insulator which is subjected to gas-phase infiltration as the third protective film on the dielectric film is aluminum oxide.

33. The method for manufacturing a semiconductor device as claimed in claim 32, wherein the aluminum oxide is formed at a processing temperature of 220° C.-400° C. by means of ALD employing ozone and trimethylaluminum as a reaction gas.

34. The method for manufacturing a semiconductor device as claimed in claim 30, wherein the main component of the insulator which is subjected to gas-phase infiltration as the third protective film on the dielectric film is silicon dioxide.

35. The method for manufacturing a semiconductor device as claimed in claim 34, wherein the silicon dioxide is formed at a processing temperature of 300° C.-400° C. by means of ALD employing ozone and tris(dimethylamino)silane as a reaction gas.

36. The method for manufacturing a semiconductor device as claimed in claim 34, wherein the silicon dioxide is formed at a processing temperature of 350° C.-400° C. by means of ALD employing ozone and dichlorosilane as a reaction gas.

37. The method for manufacturing a semiconductor device as claimed in claim 21, further comprising, before forming the first protective film comprising titanium oxide as the main component, subjecting the dielectric film to heat treatment at a temperature selected from the range between 220° C. and 450° C. under an oxidizing atmosphere.
